(19) United States
(12) Patent Application Publication
(10) Pub. No.: US 2025/0368854 A1
(43) Pub. Date: Dec. 4, 2025

(54) CURABLE SILICONE COMPOSITION, AN ENCAPSULANT, AND AN OPTICAL SEMICONDUCTOR DEVICE

(71) Applicants: DuPont Specialty Materials Korea Ltd., Cheonan-si (KR); DuPont Toray Specialty Materials Kabushiki Kaisha, Tokyo (JP)

(72) Inventors: Shunya Takeuchi, Chiba (JP); Akihiko Kobayashi, Chiba (JP); Hyunji Kang, Hwaseong-Si (KR)

(73) Assignees: DuPont Specialty Materials Korea Ltd., Cheonan-si (KR); DuPont Toray Specialty Materials Kabushiki Kaisha, Tokyo (JP)

(21) Appl. No.: 19/223,128

(22) Filed: May 30, 2025

(30) Foreign Application Priority Data
Jun. 3, 2024 (JP) 2024-089961

(51) Int. Cl. C09D 183/04; C08G 77/00; C08G 77/12; C08G 77/20; H10H 20/854

(52) U.S. Cl. CPC C09D 183/04; C08G 77/12; C08G 77/20; H10H 20/854; C08G 77/70; C08G 77/80

(57) ABSTRACT

A curable silicone composition includes (A) a resinous alkenyl group-containing organopolysiloxane comprising (A-1) and (A-2); (B) at least one organopolysiloxane; (C) a silicone reactive compatibilizer which is an organopolysiloxane having no more than 6 siloxane units; (D) a curing catalyst; and (E) a reaction inhibitor.

### CROSS-REFERENCE TO RELATED APPLICATION

This application claims priority to and all benefits of Japanese Patent Application No. 2024-089961, filed Jun. 3, 2024, the content of which is incorporated herein by reference in its entirety.

### TECHNICAL FIELD

The present disclosure relates to a curable silicone composition, and more specifically relates to a curable silicone composition that is suitable for use in encapsulating materials for optical semiconductors. The present disclosure also relates to an optical semiconductor device that is encapsulated with an encapsulating material comprising a cured product of such a curable silicone composition.

### BACKGROUND

When curable silicone compositions are cured, they form cured products having excellent heat resistance, cold resistance, electrical insulation properties, weather resistance, water repellency, and transparency, and so they are used in a wide range of industrial fields. In particular, as compared with other organic materials, these cured products are less prone to discolouration, with less deterioration of physical properties such as durability, and are thus widely used for optical materials, particularly silicone encapsulating materials used in optical semiconductor devices such as light-emitting diodes.

For example, Patent Document 1 discloses a curable organopolysiloxane composition, comprising: (A) a branched organopolysiloxane that has at least one silicon-bonded alkenyl group and at least one silicon-bonded aryl group per molecule, and that has siloxane units represented by general formula RSiO_{3/2} (where R is an optionally substituted monovalent hydrocarbon group); (B) a linear organopolysiloxane having at least one silicon-bonded aryl group per molecule, wherein both terminal ends of the branched chain are blocked by silicon-bonded hydrogen atoms; (C) a hydrosilylation reaction catalyst; and (D) a low-molecular weight siloxane represented by the following average formula: (R⁵₃SiO_{1/2})_{f}(R⁵₂SiO_{2/2})_{g}(R⁵SiO_{3/2})ₕ(SiO_{4/2})ᵢ(where each R⁵, which may be the same or different, is independently selected from optionally substituted monovalent hydrocarbon groups, at least one R⁵ per molecule is an alkenyl group, provided that the alkenyl group and silicon atom ratio is 0.3:1, and f, g, h, and i are independently 0 or a positive number), wherein the siloxane weight-average molecular weight Mw is less than 1,000 g/mol.

Patent Document 2 discloses a curable composition, comprising:
(A) a mixture of
a first cross linked polyorganosiloxane that includes a siloxane unit of the following Formula A and a siloxane unit of the following Formula B:

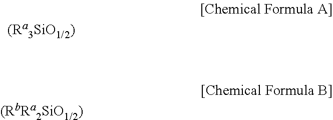

(in Chemical Formulas A and B, Ra is an alkyl group, and Rb is an alkenyl group), where the ratio (B/(A+B)) of the number of mols of siloxane unit (B) of Chemical Formula B relative to the total number of mols of siloxane units (A+B) of Chemical Formulas A and B is within the range of 0.1 to 0.35, and the molar ratio (Ar/Si) of aryl groups (Ar) relative to silicon atoms (Si) is 0.3 or less, and
a second cross linked polyorganosiloxane that includes a siloxane unit of Chemical Formula A and a siloxane unit of Chemical Formula B, where the ratio (B/(A+B)) of the number of mols of siloxane unit (B) of Chemical Formula B relative to the total number of mols of siloxane units (A+B) of Chemical Formulas A and B is different from that of the first cross linked polyorganosiloxane and is within the range of 0.2 to 1, and the molar ratio (Ar/Si) of aryl groups (Ar) relative to silicon atoms (Si) is 0.3 or less; and
(B) a polyorganosiloxane that includes silicon atom-bonded hydrogen atoms and aryl groups, where the molar ratio of aryl groups (Ar) relative to silicon atoms (Si) is 0.25 or more, and that has 3 to 10 silicon atoms.

However, problems of conventional curable silicone compositions are that the cured products thereof lack sufficient hardness or strength, and have poor thermal stability.

In addition, other objects, desirable features and characteristics will become apparent from the subsequent summary and detailed description, and the appended claims, taken in conjunction with this background.

### BRIEF SUMMARY

This disclosure provides a curable silicone composition including:
(A) a resinous alkenyl group-containing organopolysiloxane including (A-1) and (A-2) wherein:
(A-1) is a resinous alkenyl group-containing organopolysiloxane that includes at least two alkenyl groups and at least one aryl group per molecule;
(A-2) is an MQ resinous alkenyl group-containing organopolysiloxane that is solid at 25° C., that includes at least two alkenyl groups per molecule, and that contains no aryl groups;
(B) at least one organopolysiloxane chosen from (B-1) and (B-2) wherein:
(B-1) is a linear organopolysiloxane including 7 to 35 siloxane units, that includes at least two silicon atom-bonded hydrogen atoms per molecule or at least two alkenyl groups per molecule in a terminal of the molecular chain;
(B-2) is a resinous organohydrogenpolysiloxane including at least two silicon atom-bonded hydrogen atoms per molecule;
(C) a silicone reactive compatibilizer which is an organopolysiloxane having no more than 6 siloxane units, chosen from:
(C-1) linear organohydrogenpolysiloxanes including at least two silicon atom-bonded hydrogen atoms and at least one aryl group per molecule,
(C-2) MQ resinous organopolysiloxanes including at least two alkenyl groups per molecule, and
(C-3) cyclic organopolysiloxanes including at least two alkenyl groupsper molecule;
(D) a curing catalyst; and
(E) a reaction inhibitor,
   wherein
the content of aryl groups included in component (A-1) is more than 0% by mass and not more than 30% by mass relative to the total mass of component (A-1);
the organopolysiloxane of (B) comprises at least one organohydrogenpolysiloxane;
when component (C) includes component (C-1), the content of component (C-1) is 20% by mass to 48% by mass relative to the total content of component (A-1) and component (C-1);
the content of resinous alkenyl group-containing organopolysiloxanes that have at least two alkenyl groups and at least one aryl group per molecule, and have an aryl group content of more than 30% by mass, is 15% by mass or less based on the total mass of the curable silicone composition; and
the content of linear organopolysiloxanes including more than 35 siloxane units is 15% by mass or less based on the total mass of the curable silicone composition.

An object of the present disclosure is to provide a curable silicone composition capable of forming a cured product that has better transparency as well as high hardness and strength, and that has better crack resistance during changes in temperature.

Another object of the present disclosure is to provide an encapsulating material obtained by curing the curable silicone composition of the present disclosure. Yet another objective of the present disclosure is to provide an optical semiconductor device that is encapsulated with the encapsulating material of the present disclosure.

As a result of extensive research to solve the above-mentioned problems, it was discovered that a curable organopolysiloxane composition that comprises at least components (A) through (E) specified in the present disclosure and that satisfies the following specified conditions is capable of forming a cured product that has better transparency as well as high hardness and strength, and that has better crack resistance during changes in temperature.

### DETAILED DESCRIPTION

The following detailed description is merely exemplary in nature and is not intended to limit the present disclosure or the application and uses of the present disclosure. Furthermore, there is no intention to be bound by any theory presented in the preceding background of the present disclosure or the following detailed description. Moreover, it is contemplated that, in various non-limiting embodiments, it is to be appreciated that all numerical values as provided herein, save for the actual examples, are approximate values with endpoints or particular values intended to be read as “about” or “approximately” the value as recited.

The present invention disclosure thus relates to a curable silicone composition, comprising:
(A) a resinous alkenyl group-containing organopolysiloxane comprising (A-1) and (A-2) below:
   (A-1) resinous alkenyl group-containing organopolysiloxanes that include at least two alkenyl groups and at least one aryl group per molecule;
   (A-2) MQ resinous alkenyl group-containing organopolysiloxanes that are solids at about 25° C., that include at least two alkenyl groups per molecule, and that contain no aryl groups;
(B) at least one organopolysiloxane selected from (B-1) and (B-2) below:
   (B-1) linear organopolysiloxanes including from about 7 to about 35 siloxane units, that include at least two silicon atom-bonded hydrogen atoms per molecule or at least two alkenyl groups per molecule in a terminal of the molecular chain;
   (B-2) resinous organohydrogenpolysiloxanes including at least two silicon atom-bonded hydrogen atoms per molecule;
(C) a silicone reactive compatibilizer, which is an organopolysiloxane having no more than 6 siloxane units, selected from (C-1) linear organohydrogenpolysiloxanes including at least two silicon atom-bonded hydrogen atoms and at least one aryl group per molecule, (C-2) MQ resinous organopolysiloxanes including at least two alkenyl groups per molecule, and
   (C-3) cyclic organopolysiloxanes including at least two alkenyl groups per molecule;
(D) a curing catalyst; and
(E) a reaction inhibitor,
   wherein
the content of aryl groups included in component (A-1) is more than about 0% by mass and not more than about 30% by mass relative to the total mass of component (A-1);
the organopolysiloxanes of (B) comprise at least one organohydrogenpolysiloxane;
when component (C) includes component (C-1), the content of component (C-1) is about 20% by mass to about 48% by mass relative to the total content of component (A-1) and component (C-1);
the content of resinous alkenyl group-containing organopolysiloxanes that have at least two alkenyl groups and at least one aryl group per molecule, and have an aryl group content of more than about 30% by mass, is about 15% by mass or less based on the total mass of the curable silicone composition; and
the content of linear organopolysiloxanes including more than about 35 siloxane units is about 15% by mass or less based on the total mass of the curable silicone composition.

The content of component (A-1) is preferably from about 5 to about 50% by mass based on the total mass of the curable silicone composition of the present disclosure.

Component (C-1) is preferably included.

The total content of component (C) is preferably from about 3 to about 50% by mass based on the total mass of the curable silicone composition.

The total content of component (A-2) and component (B-1) is preferably about 20% by mass or more based on the total mass of the curable silicone composition of the present disclosure.

The total content of component (C) is preferably about 10% by mass or more relative to the total content of component (A-2), component (B-1), and component (C).

The content of component (A-1) is preferably about 60% by mass or less relative to the total content of component (A-1), component (A-2), and component (B-1).

The present disclosure also relates to an encapsulating material or adhesive comprising the curable silicone composition according to the present disclosure.

The present disclosure furthermore relates to an optical semiconductor device that is encapsulated with the encapsulating material according to the present disclosure.

The curable silicone composition according to the present disclosure is capable of forming a cured product that has better transparency as well as high hardness and strength, and that has better crack resistance during changes in temperature.

The curable silicone composition according to the present disclosure comprises at least:
a curable silicone composition, comprising:
(A) a resinous alkenyl group-containing organopolysiloxane comprising (A-1) and (A-2) below;
   (A-1) resinous alkenyl group-containing organopolysiloxanes that include at least two alkenyl groups and at least one aryl group per molecule;
   (A-2) MQ resinous alkenyl group-containing organopolysiloxanes that are solids at 25° C., that include at least two alkenyl groups per molecule, and that contain no aryl groups;
(B) at least one organopolysiloxane selected from (B-1) and (B-2) below:
   (B-1) a linear organopolysiloxane including up to 35 siloxane units, that includes at least two silicon atom-bonded hydrogen atoms per molecule or at least two alkenyl groups per molecule in a terminal of the molecular chain;
   (B-2) resinous organohydrogenpolysiloxanes including at least two silicon atom-bonded hydrogen atoms per molecule;
(C) a silicone reactive compatibilizer, which is an organopolysiloxane having a weight-average molecular weight of less than about 750, selected from (C-1) linear organohydrogenpolysiloxanes including at least two silicon atom-bonded hydrogen atoms and at least one aryl group per molecule, (C-2) MQ resinous organopolysiloxanes including at least two alkenyl groups per molecule, and (C-3) cyclic organopolysiloxanes including at least two alkenyl groups per molecule;
(D) a curing catalyst; and
(E) a reaction inhibitor,
   wherein
the content of aryl groups included in component (A-1) is more than about 0% by mass and not more than about 30% by mass relative to the total mass of component (A-1);
the organopolysiloxanes of (B) comprise at least one organohydrogenpolysiloxane;
when component (C) includes component (C-1), the content of component (C-1) is about 20% by mass to about 48% by mass relative to the total content of component (A-1) and component (C-1);
the content of resinous alkenyl group-containing organopolysiloxanes that have at least two alkenyl groups and at least one aryl group per molecule, and have an aryl group content of more than about 30% by mass, is about 15% by mass or less based on the total mass of the curable silicone composition; and
the content of linear organopolysiloxanes including more than about 35 siloxane units is about 15% by mass or less based on the total mass of the curable silicone composition.

The components of the curable silicone composition of the present disclosure are described in detail below.

Resinous alkenyl group-containing organopolysiloxane Component (A) is a resinous alkenyl group-containing organopolysiloxane having at least two alkenyl groups per molecule, which comprises at least: (A-1) a resinous alkenyl group-containing organopolysiloxane that includes at least two alkenyl groups and at least one aryl group per molecule; and (A-2) an MQ resinous alkenyl group-containing organopolysiloxane that is a solid at about 25° C., that includes at least two alkenyl groups per molecule, and that comprises no aryl groups.

In the present specification, the term “resinous” means having a branched structure or a 3D network structure in the molecular structure. The structure of the resinous organopolysiloxane thus includes a siloxane unit represented by RSiO_{3/2} (T unit) and/or a siloxane unit represented by SiO_{4/2} (Q unit). In one embodiment, resinous means an organopolysiloxane in which the ratio of T units and Q units relative to all siloxane units per molecule is about 10% or more, is preferably about 20% or more, and is more preferably about 30% or more. In the present specification, R in the siloxane units means a silicon atom-bonded organic group, such as a monovalent hydrocarbon group.

In the present specification, MQ resins mean an organopolysiloxane consisting only of a siloxane unit represented by R³—SiO_{1/2} (M unit) and a siloxane unit represented by SiO_{4/2} (Q unit).

Examples of the alkenyl groups in component (A) include C2-12 alkenyl groups such as vinyl, allyl, butenyl, pentenyl, hexenyl, heptenyl, octenyl, nonenyl, decenyl, undecenyl, and dodecenyl groups, and preferably vinyl. Examples of aryl groups include C6-20 aryl groups such as phenyl, tolyl group, xylyl group, and naphthyl groups.

Examples of silicon atom-bonded organic groups other than alkenyl and aryl groups in component (A) include optionally halogen-substituted monovalent hydrocarbon groups other than alkenyl and aryl groups, for example, C1-12 alkyl groups such as methyl, ethyl, propyl, isopropyl, butyl, isobutyl, tert-butyl, pentyl, neopentyl, hexyl, cyclohexyl, heptyl, octyl, nonyl, decyl, undecyl, and dodecyl groups; and any of these groups in which some or all of the hydrogen atoms are substituted with halogen atoms such as fluorine, chlorine, and bromine atoms. The silicon atoms in component (A) may also have a small quantity of hydroxyl groups or alkoxy groups such as methoxy or ethoxy groups, provided that the object of the present disclosure is not thereby compromised. Silicon atom-bonded organic groups other than alkenyl groups in component (A) are preferably selected from among C1-6 alkyl groups, and methyl in particular. In one embodiment, component (A) does not contain any epoxy group-containing organic groups as silicon atom-bonded organic groups.

The resinous alkenyl group-containing organopolysiloxane of component (A) can be a resinous alkenyl group-containing organopolysiloxane that does not contain any epoxy group-containing organic groups as silicon atom-bonded organic groups.

(a-1) Resinous Alkenyl Group-Containing Organopolysiloxanes that Include at Least Two Alkenyl Groups and at Least One Aryl Group Per Molecule

The curable silicon composition according to the present disclosure comprises the following as component (A): (A-1) a resinous alkenyl group-containing organopolysiloxane that includes at least two alkenyl groups and at least one aryl group per molecule. One type of (A-1) resinous alkenyl group-containing organopolysiloxane may be included, or two or more types of (A-1) resinous alkenyl group-containing organopolysiloxanes may be included.

According to one embodiment of the present disclosure, component (A-1) may preferably be represented by the following average unit formula (I):

Average unit formula (I): (R¹₃SiO_{1/2})ₐ(R¹₂SiO_{2/2})_{b}(R¹SiO_{3/2})_{c}(SiO_{4/2})_{d}(XO_{1/2})ₑ

(in Formula (I), R¹ are optionally halogen-substituted monovalent hydrocarbon groups, which may be the same or different, provided that at least two R¹ are alkenyl groups and at least one R¹ is an aryl group per molecule; 0a≤1, 0≤<1, 0≤c<0.9, 0≤d<0.5, and 0≤e<0.4; a+b+c+d=1.0; and c+d>0). The symbol e represents the number of (XO) groups per silicon atom (ratio of the number of (XO) groups per silicon atom). In the specification of the present application, “unit formula” is a chemical formula that represents the proportion of siloxane units represented by (SiO_{x/2}) (x is an integer of 1 to 4) that are present, and “structural formula” is a chemical formula that indicates the actual number of siloxane units per molecule.

Examples of optionally halogen-substituted monovalent hydrocarbon groups represented by R¹ in Formula (I) above include: C1-12 alkyl groups such as methyl, ethyl, propyl, isopropyl, butyl, isobutyl, tert-butyl, pentyl, neopentyl, hexyl, cyclohexyl, heptyl, octyl, nonyl, decyl, undecyl, and dodecyl groups; C6-20 aryl groups such as phenyl, tolyl, xylyl, and naphthyl groups; C7-20 aralkyl groups such as benzyl, phenethyl, and phenylpropyl groups; C2-12 alkenyl groups such as vinyl, allyl, butenyl, pentenyl, hexenyl, heptenyl, octenyl, nonenyl, decenyl, undecenyl, and dodecenyl groups; and any of these groups in which some or all of the hydrogen atoms are substituted with halogen atoms such as fluorine, chlorine, and bromine atoms. R¹ is preferably selected from among C1-6 alkyl groups, and methyl in particular, C2-6 alkenyl groups, and vinyl in particular, and C6-20 aryl groups, and phenyl in particular.

In Formula (I) above, X is a hydrogen atom or an alkyl group. Preferred examples of alkyl groups represented by X include C1-3 alkyl groups, specifically, methyl, ethyl, and propyl groups.

In Formula (I) above, a is preferably in the range of about 0.1≤a≤0.6, more preferably in the range of about 0.15≤a≤0.5, and even more preferably in the range of about 0.2≤a≤0.4. In Formula (I) above, b is preferably in the range of about 0≤b≤0.3, more preferably in the range of about 0≤b≤0.2, and particularly in the range of about 0≤b≤0.1. In Formula (II) above, c is preferably in the range of about 0.4≤c<0.9, more preferably in the range of about 0.5≤c≤0.85, and particularly in the range of about 0.6≤≤≤0.8. In Formula (I) above, d is preferably in the range of about 0d≤0.3, more preferably in the range of about 0≤d≤0.5, and particularly in the range of about 0≤d≤0.1. In Formula (I) above, e is preferably in the range of about 0≤e≤0.15, more preferably in the range of about 0≤e≤0.1, and particularly in the range of about 0≤e≤0.05.

According to a preferred embodiment of the present disclosure, the resinous alkenyl group-containing organopolysiloxane of component (A-1) is such that c in Formula (I) above is greater than 0, specifically, includes at least one T unit. The resinous organopolysiloxane of component (A-1) may or may not, but preferably does not, include a Q unit.

According to a preferred embodiment of the present disclosure, the resinous alkenyl group-containing organopolysiloxane of component (A-1) may or may not contain, but preferably does not contain, a siloxane unit represented by R₂—SiO_{2/2} (D unit). According to a preferred embodiment of the present invention disclosure, the resinous alkenyl group-containing organopolysiloxane of component (A-1) is an MT resinous alkenyl group-containing organopolysiloxane consisting of only siloxane units represented by R3-SiO1/2 (M units) and T units.

According to a preferred embodiment of the present disclosure, the resinous alkenyl group-containing organopolysiloxane of component (A-1) includes terminal alkenyl groups. The resinous organopolysiloxane of component (A-1) preferably has an alkenyl group in the M unit, and may or may not, but preferably does not, include an alkenyl group in molecular side chains (D and T units).

The content of the alkenyl groups in all of the silicon atom-bonded organic groups of the resinous alkenyl group-containing organopolysiloxane of component (A-1) is not particularly limited, but may be, for example, about 1 mol % or more, preferably about 3 mol % or more, and more preferably about 5 mol % or more of the total of the silicon atom-bonded organic groups, and can be about 30 mol % or less, preferably about 20 mol %, and more preferably about 15 mol % or less of the total of the silicon atom-bonded organic groups. In the present specification, the alkenyl group content in organopolysiloxane components may be determined by employing analysis such as Fourier transform infrared spectrophotometry (FT-IR) or nuclear magnetic resonance (NMR), or by employing the titration method described below.

A method for quantifying alkenyl groups in the components by employing a titration method will be described. The alkenyl group content in organopolysiloxane components can be accurately quantified by employing a titration method generally known as the Wijs method. The principles are described below. First, the alkenyl groups in the organopolysiloxane starting material and iodine monochloride are subjected to an addition reaction as shown in Formula (1). Next, according to the reaction shown in Formula (2), an excess amount of iodine monochloride is reacted with potassium iodide, thereby freeing iodine. The freed iodine is subjected to titration with a sodium thiosulfate solution.

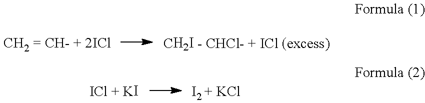

The amount of alkenyl groups in the component can be quantified from the difference between the amount of sodium thiosulfate required for titration and the titration amount of a separately prepared blank solution.

The aryl group content of component (A-1) (percent by mass of aryl groups relative to the total mass (or molecular weight) of component (A-1)) is more than about 0% by mass and not more than about 30% by mass. The alkenyl group content of component (A-1) is preferably about 5% by mass or more, more preferably about 10% by mass or more, and even more preferably about 15% by mass or more. The aryl group content of component (A-1) can be about 25% by mass or less. In the present specification, the content of aryl groups included in organopolysiloxane components can also be determined by employing analysis such as Fourier transform infrared spectrophotometry (FT-IR) or nuclear magnetic resonance (NMR).

The organopolysiloxane of component (A-1) is preferably a solid or semi-solid at 25° C. The weight-average molecular weight of the organopolysiloxane of component (A-1) is not particularly limited, but is preferably in the range of from about 500 to about 10,000. In the present specification, the weight-average molecular weight can be determined by GPC.

The content of component (A-1) is not particularly limited, but can be about 5% by mass or more, preferably about 10% by mass or more, and more preferably about 15% by mass or more, based on the total mass of the curable silicone composition of the present disclosure or the total mass of all organopolysiloxane components included in the composition. The content of component (A-1) is also preferably about 50% by mass or less, more preferably about 40% by mass or less, and even more preferably about 35% by mass or less, based on the total mass of the curable silicone composition of the present disclosure or the total mass of all organopolysiloxane components included in the composition according to the present disclosure. In the present specification, “all organopolysiloxane components” means all organopolysiloxane components included in the curable silicone composition of the present disclosure, specifically, includes alkenyl group-containing organopolysiloxanes, organohydrogenpolysiloxanes, organopolysiloxanes serving as reactive diluents, and organopolysiloxanes containing epoxy group-containing organic groups. Organopolysiloxane components other than these organopolysiloxane components may also be included.

In one embodiment, the content of component (A-1) is from about 5 to about 50% by mass, preferably from about 10 to about 40% by mass, and even more preferably from about 15 to about 35% by mass, based on the total mass of the curable silicone composition of the present disclosure or the total mass of all organopolysiloxane components included in the composition according to the present disclosure.

(A-2) MQ Resinous Alkenyl Group-Containing Organopolysiloxanes that are Solids at about 25° C., that Include at Least Two Alkenyl Groups Per Molecule, and that Contain No Aryl Groups

The MQ resinous alkenyl group-containing organopolysiloxane of component (A-2) is a solid at about 25° C. In the present specification, pressure conditions are standard pressure (atmospheric pressure, 1 atm), unless otherwise specified.

In a preferred embodiment of the present disclosure, the MQ resinous alkenyl group-containing organopolysiloxane of component (A-2) is preferably represented by the following average unit formula (II).

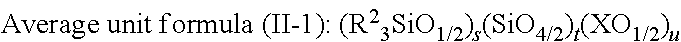

In the formula, R² indicates optionally halogen-substituted monovalent hydrocarbon groups other than aryl groups, which may be the same or different, provided that at least one R² per molecule is an alkenyl group, 0≤s≤1, 0<t<1, 0≤u0.4, and s+t=1). The symbol u represents the number of (XO) groups per silicon atom (ratio of the number of (XO) groups per silicon atom).

Examples of optionally halogen-substituted monovalent hydrocarbon groups represented by R² in Formula (II-1) above include: C1-12 alkyl groups such as methyl, ethyl, propyl, isopropyl, butyl, isobutyl, tert-butyl, pentyl, neopentyl, hexyl, cyclohexyl, heptyl, octyl, nonyl, decyl, undecyl, and dodecyl groups; C2-12 alkenyl groups such as vinyl, allyl, butenyl, pentenyl, hexenyl, heptenyl, octenyl, nonenyl, decenyl, undecenyl, and dodecenyl groups; and any of these groups in which some or all of the hydrogen atoms are substituted with halogen atoms such as fluorine, chlorine, and bromine atoms. R² is preferably selected from C1-6 alkyl groups, and methyl in particular, or C2-6 alkenyl groups, and vinyl in particular.

In Formula (II-1) above, X is a hydrogen atom or an alkyl group. Preferred examples of alkyl groups represented by X include C1-3 alkyl groups, specifically, methyl, ethyl, and propyl groups.

In formula (II-1), s is preferably in the range of about 0.2≤s≤0.8, more preferably in the range of about 0.3≤s≤0.7, and even more preferably in the range of about 0.4≤s≤0.6. In formula (II-1) above, t is preferably in the range of about 0.2≤t≤0.8, more preferably in the range of about 0.3≤t≤0.7, and in particular in the range of about 0.4≤t≤0.6. In formula (II-1) above, u is preferably in the range of about 0≤u≤0.2, more preferably in the range of about 0≤u≤0.15, and in particular in the range of about 0≤u≤0.1.

In another preferred embodiment of the present disclosure, the MQ resinous alkenyl group-containing organopolysiloxane of component (A-2) is preferably represented by the following average unit formula (II-2).

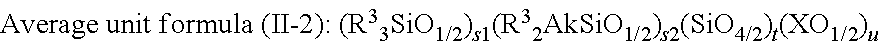

In the formula, R³ indicates optionally halogen-substituted monovalent hydrocarbon groups other than alkenyl or aryl groups, which may be the same or different, Ak is an alkenyl group, 0<s1<1, 0<s2<1, 0<<1, 0≤u<0.4, and s1+s2+t=1. The symbol u represents the number of (XO) groups per silicon atom (ratio of the number of (XO) groups per silicon atom).

Examples of the optionally halogen-substituted monovalent hydrocarbon groups other than alkenyl or aryl groups of R³ in formula (II-2) include C1-12 alkyl groups such as methyl, ethyl, propyl, isopropyl, butyl, isobutyl, tert-butyl, pentyl, neopentyl, hexyl, cyclohexyl, heptyl, octyl, nonyl, decyl, undecyl, and dodecyl groups; and any of these groups in which some or all of the hydrogen atoms are substituted with halogen atoms such as fluorine, chlorine, and bromine atoms. R³ is preferably selected from C1-6 alkyl groups, and methyl in particular.

Examples of the alkenyl groups represented by Ak in Formula (II-2) above include C2-12 alkenyl groups such as vinyl, allyl, butenyl, pentenyl, hexenyl, heptenyl, octenyl, nonenyl, decenyl, undecenyl, and dodecenyl groups, and preferably vinyl.

In Formula (II-2) above, X is a hydrogen atom or an alkyl group. Preferred examples of alkyl groups represented by X include C1-3 alkyl groups, specifically, methyl, ethyl, and propyl groups.

In formula (II-2), s1 is preferably in the range of about 0.2≤s1≤0.7, more preferably in the range of about 0.3≤s1≤0.6, and even more preferably in the range of about 0.35≤s1≤0.5. In formula (II-2), s2 is preferably in the range of about 0.001≤s2≤0.2, more preferably in the range of about 0.005≤s2≤0.15, and even more preferably in the range of about 0.008≤s2≤0.1. In formula (II-2) above, t is preferably in the range of about 0.25t≤0.8, more preferably in the range of about 0.3≤t≤0.7, and in particular in the range of about 0.4≤t≤0.6. In formula (II-2) above, u is preferably in the range of about 0≤u≤0.2, more preferably in the range of about 0≤u≤0.15, and in particular in the range of about 0≤u≤0.1.

The content of the alkenyl groups in all of the silicon atom-bonded organic groups of the MQ resinous alkenyl group-containing organopolysiloxane of component (A-2) is not particularly limited, but may be, for example, about 0.1 mol % or more, preferably about 0.3 mol % or more, and more preferably about 0.5 mol % or more of the total of the silicon atom-bonded organic groups, and can be about 20 mol % or less, preferably about 15 mol % or less, and more preferably about 10 mol % or less of the total of the silicon atom-bonded organic groups.

According to one embodiment of the present disclosure, an example of the weight-average molecular weight of the MQ resinous alkenyl-group containing organopolysiloxane of component (A-2) includes, but is not particularly limited to, the range of from about 2,000 to about 5,000.

The proportion of Q units (mol %) relative to the total of M and Q units in the MQ resinous alkenyl group-containing organopolysiloxane of component (A-2) is not particularly limited, but is usually from about 20 to about 80%, preferably from about 30 to about 70%, and more preferably from about 40 to about 60%.

The content of component (A-2) is not particularly limited, but is usually about 5% by mass or more, preferably about 10% by mass or more, and more preferably about 12% by mass or more, based on the total mass of the curable silicone composition of the present disclosure or the total mass of all organopolysiloxane components included in the composition. The content of component (A-2) is also preferably about 80% by mass or less, more preferably about 70% by mass or less, and even more preferably about 65% by mass or less, based on the total mass of the curable silicone composition.

In one embodiment, the content of component (A-2) is from about 5 to about 80% by mass, preferably from about 10 to about 70% by mass, and even more preferably from about 15 to about 65% by mass, based on the total mass of the curable silicone composition of the present disclosure or the total mass of all organopolysiloxane components included in the composition.

(B) At least one organopolysiloxane, selected from: (B-1) linear organopolysiloxanes including from about 7 to about 35 siloxane units, that include at least two silicon atom-bonded hydrogen atoms per molecule or at least two alkenyl groups per molecule in a terminal of the molecular chain; and (B-2) resinous organohydrogenpolysiloxanes including at least two silicon atom-bonded hydrogen atoms per molecule

The curable silicone composition according to the present disclosure comprises, as component (B), an organopolysiloxane selected from: (B-1) linear organopolysiloxanes including from about 7 to about 35 siloxane units, that include at least two silicon atom-bonded hydrogen atoms per molecule or at least two alkenyl groups per molecule in a terminal of the molecular chain; and (B-2) resinous organohydrogenpolysiloxanes including at least two silicon atom-bonded hydrogen atoms per molecule. The curable silicone composition according to the present disclosure may comprise, as component (B), either component (B-1) or component (B-2), or may comprise both component (B-1) and component (B-2).

However, the organopolysiloxane (B) comprises at least one organohydrogenpolysiloxane in order to cross link component (A) noted above.

Component (B-1) is a linear organopolysiloxane including from about 7 to about 35 siloxane units, that includes at least two silicon atom-bonded hydrogen atoms per molecule or at least two alkenyl groups per molecule in a terminal of the molecular chain. Specifically, component (B-1) is a linear organopolysiloxane containing from about 7 to about 35 siloxane units, which is: (B-1-1) a linear organohydrogenpolysiloxane containing at least two silicon atom-bonded hydrogen atoms per molecule in a molecular chain terminal; or (B-1-2) a linear alkenyl group-containing organopolysiloxane containing at least two alkenyl groups per molecule in a molecular chain terminal. The curable silicone composition according to the present disclosure may comprise one type of epoxy group-containing organopolysiloxane as component (B-1), or may comprise two or more types of epoxy group-containing organopolysiloxanes as component (B-1).

The (B-1-1) linear organohydrogenpolysiloxane containing from about 7 to about 35 siloxane units that comprises at least two silicon atom-bonded hydrogen atoms per molecule in a molecular chain terminal does not contain any alkenyl groups as the silicon atom-bonded organic group. The (B-1-2) linear organohydrogenpolysiloxane containing from about 7 to about 35 siloxane units that comprises at least two alkenyl groups per molecule in a molecular chain terminal does not contain any silicon atom-bonded hydrogen atoms.

Examples of silicon atom-bonded groups other than alkenyl groups in component (B-1) include optionally halogen-substituted monovalent hydrocarbon groups other than alkenyl groups, for example, C1-12 alkyl groups such as methyl, ethyl, propyl, isopropyl, butyl, isobutyl, tert-butyl, pentyl, neopentyl, hexyl, cyclohexyl, heptyl, octyl, nonyl, decyl, undecyl, and dodecyl groups; C6-20 aryl groups such as phenyl, tolyl, xylyl, and naphthyl groups; C7-20 aralkyl groups such as benzyl, phenethyl, and phenylpropyl groups; and any of these groups in which some or all of the hydrogen atoms are substituted with halogen atoms such as fluorine, chlorine, and bromine atoms. The silicon atoms in component (B-1) may also have a small quantity of hydroxyl groups or alkoxy groups such as methoxy or ethoxy groups, provided that the object of the present disclosure is not thereby compromised. Silicon atom-bonded organic groups other than alkenyl groups in component (B-1) are preferably selected from among C1-6 alkyl groups, and methyl in particular.

Component (B-1) comprises from about 7 to about 35 siloxane units. Component (B-1) preferably comprises from about 8 to about 30 siloxane units, and more preferably comprises from about 10 to about 25 siloxane units.

According to one embodiment of the present disclosure, component (B-1) comprises a linear organohydrogenpolysiloxane represented by the following average structural formula (III-1) as component (B-1-1):

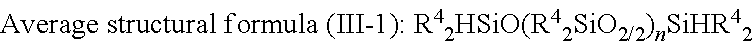

In Formula (III-1), R⁴ are optionally halogen-substituted monovalent hydrocarbon groups other than alkenyl groups, which may be the same or different, and n is from about 6 to about 34.

Optionally halogen-substituted monovalent hydrocarbon groups other than alkenyl groups represented by R⁴ in Formula (III-1) above are described above.

In Formula (III-1) above, n is preferably from about 7 to about 30, and more preferably from about 8 to about 25.

According to one embodiment of the present disclosure, component (B-1) comprises a linear alkenyl group-containing organopolysiloxane represented by the following average structural formula (III-2) as component (B-1-2):

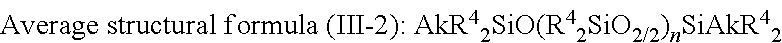

In Formula (III-2), R⁴ are optionally halogen-substituted monovalent hydrocarbon groups other than alkenyl groups, which may be the same or different, Ak is an alkenyl group, and n is from about 6 to about 34.

R⁴ and n in Formula (III-2) above are as defined in Formula (III-1) above. In Formula (III-2) above, Ak is as defined in Formula (II-2) above.

According to an embodiment of the present disclosure, the organopolysiloxane of component (B-1) is exemplified by having a low aryl group content. The aryl group content in component (B-1) (mol % of aryl groups in all silicon atom-bonded organic groups) is, for example, about 10 mol % or less, preferably about 5 mol % or less, more preferably about 3 mol % or less, even more preferably about 1 mol % or less, and in particular about 0.5 mol % or less. In a preferred embodiment, component (B-1) comprises no aryl groups.

When the curable silicone composition of the present disclosure includes component (B-1), the content of component (B-1) is not particularly limited, but is usually about 1% by mass or more, preferably about 3% by mass or more, and more preferably about 5% by mass or more, based on the total mass of the curable silicone composition of the present disclosure or the total mass of all organopolysiloxane components included in the composition. The content of component (B-1) is also preferably about 40% by mass or less, more preferably about 30% by mass or less, and even more preferably about 25% by mass or less, based on the total mass of the curable silicone composition.

In one embodiment, the content of component (B-1) is 1 to about 40% by mass, preferably from about 3 to about 30% by mass, and even more preferably from about 5 to about 25% by mass, based on the total mass of the curable silicone composition of the present disclosure or the total mass of all organopolysiloxane components included in the composition.

Component (B-2) is a resinous organohydrogenpolysiloxane including at least two silicon atom-bonded hydrogen atoms per molecule. The curable silicone composition according to the present disclosure may comprise one type of a (B-2) resinous organohydrogenpolysiloxane, or may comprise two or more types of (B-2) resinous organohydrogenpolysiloxanes.

Examples of silicon atom-bonded organic groups other than silicon atom-bonded hydrogen atoms contained in component (B-2) include the above-mentioned optionally halogen-substituted monovalent hydrocarbon groups other than alkenyl groups, which arc preferably selected from C1-6 alkyl groups, particularly methyl, and C6-20 aryl groups, particularly phenyl.

The resinous organohydrogenpolysiloxane of component (B-2) is preferably selected from: (B-2-1) MT resinous organohydrogenpolysiloxanes consisting of only M and T units; and (B-2-2) MQ resinous organohydrogenpolysiloxanes consisting of only M and Q units. The resinous organohydrogenpolysiloxane of component (B-2) may contain either or both of (B-2-1) MT resinous organohydrogenpolysiloxanes and (B-2-2) MQ resinous organohydrogenpolysiloxanes.

The resinous organohydrogenpolysiloxane of component (B-2) may or may not, but preferably does not, include a D unit. The resinous organohydrogenpolysiloxane of component (B-2) also preferably has a silicon atom-bonded hydrogen atom in the M unit.

Component (B-2) comprises an MT resinous organohydrogenpolysiloxane represented by the following average unit formula (IV-1) as component (B-2-1):

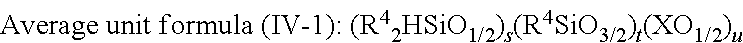

In Formula (IV-1), R⁴ are optionally halogen-substituted monovalent hydrocarbon groups other than alkenyl groups, which may be the same or different, about 0<<1, 0<t<1, 0≤u<0.4, and s+t=1. The symbol u represents the number of (XO) groups per silicon atom (ratio of the number of (XO) groups per silicon atom).

R⁴ in Formula (IV-1) above are as defined in Formula (III-1) above. In Formula (IV-1) above, X is as defined in formula (I) above.

In Formula (IV-1), s is preferably in the range of about 0.3≤s≤0.9, more preferably in the range of about 0.4≤s≤0.8, and even more preferably in the range of about 0.5≤s≤≤0.7. In Formula (IV-1) above, t is preferably in the range of about 0.1≤t≤0.7, more preferably in the range of about 0.2≤t≤0.6, and in particular in the range of about 0.3≤t≤0.5. In Formula (IV-1) above, u is preferably in the range of about 0≤u≤0.2, more preferably in the range of about 0≤u≤0.15, and in particular in the range of about 0≤u≤0.1.

In one embodiment, an aryl group is included in the silicon atom-bonded organic group of component (B-2-1). The content of the aryl groups in all of the silicon atom-bonded groups of the MT resinous organohydrogenpolysiloxane of component (B-2-1) is not particularly limited, but may be, for example, about 3 mol % or more, preferably about 5 mol % or more, and more preferably about 10 mol % or more of the total of the silicon atom-bonded organic groups, and can be about 50 mol % or less, preferably about 40 mol % or less, and more preferably about 30 mol % or less of the total of the silicon atom-bonded groups.

Component (B-2) comprises an MQ resinous organohydrogenpolysiloxane represented by the following average unit formula (IV-2) as component (B-2-2):

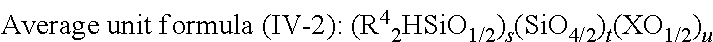

In Formula (IV-2), R⁴ are optionally halogen-substituted monovalent hydrocarbon groups other than alkenyl groups, which may be the same or different, about 0<s<1, 0<t<1, about 0≤u<0.4, and s+t=1. The symbol u represents the number of (XO) groups per silicon atom (ratio of the number of (XO) groups per silicon atom).

R⁴ in Formula (IV-2) above are as defined in Formula (III-1) above. In Formula (IV-2) above, X is as defined in formula (I) above.

In Formula (IV-2), s is preferably in the range of about 0.3≤s≤0.9, more preferably in the range of about 0.4≤s≤0.8, and even more preferably in the range of about 0.5≤s≤0.7. In Formula (IV-2) above, t is preferably in the range of about 0.1≤t≤0.7, more preferably in the range of about 0.2≤t≤0.6, and in particular in the range of about 0.3≤t≤0.5. In Formula (IV-2) above, u is preferably in the range of about 0≤u≤0.2, more preferably in the range of about 0≤u≤0.15, and in particular in the range of about 0≤≤0.1.

According to embodiment of one the present disclosure, the organohydrogenpolysiloxane of component (B-2-2) is exemplified by having a low aryl group content. The aryl group content in component (B-2-2) (mol % of aryl groups in all silicon atom-bonded organic groups) is, for example, about 10 mol % or less, preferably about 5 mol % or less, more preferably about 3 mol % or less, even more preferably about 1 mol % or less, and in particular about 0.5 mol % or less. In a preferred embodiment, component (B-2-2) comprises no aryl groups.

When the curable silicone composition of the present disclosure includes component (B-2), the content of component (B-2) is not particularly limited, but is usually about 0.5% by mass or more, preferably about 1% by mass or more, and more preferably about 1.5% by mass or more, based on the total mass of the curable silicone composition of the present disclosure or the total mass of all organopolysiloxane components included in the composition. The content of component (B-2) is also preferably about 20% by mass or less, more preferably about 15% by mass or less, and even more preferably about 10% by mass or less, based on the total mass of the curable silicone composition.

In one embodiment, the content of component (B-2) is from about 0.5 to about 20% by mass, preferably from about 1 to about 15% by mass, and even more preferably from about 1.5 to about 10% by mass, based on the total mass of the curable silicone composition of the present disclosure or the total mass of all organopolysiloxane components included in the composition.

In one embodiment, the total content of component (B) included in the curable silicone composition according to the present disclosure is about 0.5% by mass or more, preferably about 1% by mass or more, and even more preferably about 2% by mass or more, and is about 40% by mass or less, preferably about 35% by mass or less, and more preferably about 30% by mass or less, based on the total mass of the curable silicone composition of the present disclosure or the total mass of all organopolysiloxane components included in the composition.

In one embodiment, the total content of component (B) included in the curable silicone composition according to the present disclosure is from about 0.5 to about 40% by mass, preferably from about 1 to about 35% by mass, and even more preferably from about 2 to about 30% by mass, based on the total mass of the curable silicone composition of the present disclosure or the total mass of all organopolysiloxane components included in the composition.

### (C) Silicone Reactive Compatibilizer

The curable silicone composition of the present disclosure includes, as component (C), a silicone reactive compatibilizer, which is an organopolysiloxane having no more than about 6 siloxane units. The silicone reactive compatibilizer is selected from: (C-1) linear organohydrogenpolysiloxanes including at least two silicon atom-bonded hydrogen atoms and at least one aryl group per molecule; (C-2) MQ resinous organopolysiloxanes including at least two alkenyl groups per molecule; and (C-3) cyclic organopolysiloxanes including at least two alkenyl groups per molecule. Component (C) may contain each of components (C-1) through (C-3) alone or in combination.

The silicone-reactive compatibilizer of component (C) usually has two or more siloxane units. The silicone-reactive compatibilizer of component (C) is also usually a liquid at about 25° C. In the present specification, the term “silicone reactive” specifically means hydrosilylation curing reactable. Such silicone reactive compatibilizers may contain unsaturated bonds, specifically, alkenyl groups or silicon atom-bonded hydrogen atoms, as reactive groups.

### (C-1) Linear Organohydrogenpolysiloxanes Including at Least Two Silicon Atom-Bonded Hydrogen Atoms and at Least One Aryl Group Per Molecule

The curable silicone composition according to the present disclosure may also comprise, as the silicone reactive compatibilizer, a (C-1) linear organohydrogenpolysiloxane including at least two silicon atom-bonded hydrogen atoms and at least one aryl group per molecule. The curable silicone composition according to the present disclosure may comprise one type of a (C-1) linear organohydrogenpolysiloxane, or may comprise two or more types of (C) linear organohydrogenpolysiloxanes. Component (C-1) has no more than about 6 siloxane units and is therefore different from the organopolysiloxane of component (B-1), which has about 7 or more siloxane units.

Examples of aryl groups and silicon atom-bonded organic groups other than aryl groups included in component (C-1) are as described for components (A) and (B) above.

In the linear organohydrogenpolysiloxanes of component (C-1), the silicon atom-bonded hydrogen atoms are preferably included at both molecular chain terminals.

In a preferred of the present disclosure, the linear organohydrogenpolysiloxane of component (C-1) can be represented by the following average structural Formula (V-1):

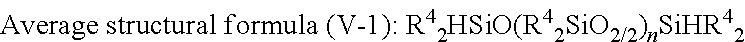

In Formula (V-1), R⁴ are optionally halogen-substituted monovalent hydrocarbon groups other than alkenyl groups, which may be the same or different, and n is from about 1 to about 5.

Examples of optionally halogen-substituted monovalent hydrocarbon groups other than alkenyl groups represented by R⁴ in formula (V-1) above are as described for Formula (III-1) and component (B-1) above.

In Formula (V-1) above, n is preferably from about 1 to about 4, and more preferably from about 1 to about 3.

In one embodiment, component (C-1) has an aryl group in a molecular side chain (specifically, a D unit). Component (C-1) may or may not, but preferably does not, include an aryl group at a molecular chain terminal (specifically, an M unit). In another preferred embodiment, component (C-1) comprises at least one (Ar₂SiO_{2/2}) structure (where Ar represents an aryl group).

According to one embodiment of the present disclosure, the aryl group content of the linear organohydrogenpolysiloxane of component (C-1) is not particularly limited, but can be, for example, about 10 mol % or more, preferably about 15 mol % or more, and more preferably about 20 mol % or more of the total of the silicon atom-bonded organic groups, and can be about 50 mol % or less, preferably about 40 mol %, and more preferably about 30 mol % or less of the total of the silicon atom-bonded organic groups.

When the curable silicone composition of the present disclosure includes component (C-1), the content of component (C-1) is not particularly limited, but can be, for example, about 1% by mass or more, preferably about 3% by mass or more, and more preferably about 5% by mass or more, based on the total mass of the curable silicone composition of the present disclosure or the total mass of all organopolysiloxane components included in the composition. The content of component (C-1) is also preferably about 40% by mass or less, more preferably about 30% by mass or less, and even more preferably about 25% by mass or less, based on the total mass of the curable silicone composition or the total mass of all organopolysiloxane components included in the composition.

In one embodiment, the content of component (C-1) is from about 1 to about 40% by mass, preferably from about 3 to about 30% by mass, and even more preferably from about 5 to about 25% by mass, based on the total mass of the curable silicone composition of the present disclosure or the total mass of all organopolysiloxane components included in the composition.

### (C-2) MQ Resinous Organopolysiloxane Containing at Least Two Alkenyl Groups Per Molecule

The curable silicone composition according to the present disclosure may also comprise, as the silicone reactive compatibilizer, (C-2) an MQ resinous organopolysiloxane consisting of only M and Q units, that comprises at least two alkenyl groups per molecule. The curable silicone composition according to the present disclosure may comprise one type of component (C-2) MQ resinous organopolysiloxane, or may comprise two or more types of component (C-2) MQ resinous organopolysiloxanes.

Component (C-2) is a liquid at about 25° C. and is therefore different from the MQ resinous alkenyl group-containing organopolysiloxane of component (A-2), which is a solid at about 25° C.

Examples of aryl groups and silicon atom-bonded organic groups other than aryl groups included in component (C-2) are as described for components (A) and (B) above.

In a preferred embodiment of the present disclosure, the MQ resinous organopolysiloxane of component (C-2) is preferably represented by the following average unit formula (V-2).

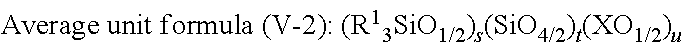

In the formula, R¹ are optionally halogen-substituted monovalent hydrocarbon groups other than alkenyl groups, which may be the same or different, about 0≤s<1, 0<t<1, 0≤u<0.4, and s+t=1. The symbol u represents the number of (XO) groups per silicon atom (ratio of the number of (XO) groups per silicon atom).

R¹ and X in Formula (V-2) above can be the same as those in formula (I) above.

In Formula (V-2), s is preferably in the range of about 0.4≤s≤0.95, more preferably in the range of about 0.5≤s≤0.9, and even more preferably in the range of about 0.55≤s≤0.85. In Formula (V-2) above, t is preferably in the range of about 0.05≤t≤0.7, more preferably in the range of about 0.1≤t≤0.6, and in particular in the range of about 0.15≤t≤0.5. In Formula (V-2) above, u is preferably in the range of about 0≤u≤0.3, more preferably in the range of about 0≤u≤0.2, and in particular in the range of about 0≤u≤0.1.

The proportion of Q units (mol %) relative to the total of M and Q units in the MQ resinous organopolysiloxane of component (C-2) is not particularly limited, but is preferably about 40% or less, and more preferably about 30% or less.

According to one embodiment of the present disclosure, the MQ resinous organopolysiloxane of component (C-2) is exemplified by having a low aryl group content. The aryl group content in component (C-2) (mol % of aryl groups in all silicon atom-bonded groups) can be, for example, about 10 mol % or less, preferably about 5 mol % or less, more preferably about 3 mol % or less, even more preferably about 1 mol % or less, and in particular about 0.5 mol % or less. In a preferred embodiment, component (C-2) comprises no aryl groups.

When the curable silicone composition of the present disclosure includes component (C-2), the content of component (C-2) is not particularly limited, but can be, for example, about 0.3% by mass or more, preferably about 0.5% by mass or more, and more preferably about 1% by mass or more, based on the total mass of the curable silicone composition of the present disclosure or the total mass of all organopolysiloxane components included in the composition. The content of component (C-2) is also preferably about 20% by mass or less, more preferably about 15% by mass or less, and even more preferably about 10% by mass or less, based on the total mass of the curable silicone composition or the total mass of all organopolysiloxane components included in the composition.

In one embodiment, the content of component (C-2) is from about 0.3 to about 20% by mass, preferably from about 0.5 to about 15% by mass, and even more preferably from about 1 to about 10% by mass, based on the total mass of the curable silicone composition of the present disclosure or the total mass of all organopolysiloxane components included in the composition.

### (C-3) Cyclic Organopolysiloxanes Containing at Least Two Alkenyl Groups Per Molecule

The curable silicone composition according to the present disclosure may also comprise, as the silicone reactive compatibilizer, (C-3) a cyclic organopolysiloxane that has least two alkenyl groups per molecule. The curable silicone composition according to the present disclosure may comprise one type of (C-3) cyclic organopolysiloxane, or may comprise two or more types of (C-3) cyclic organopolysiloxanes.

Examples of aryl groups and silicon atom-bonded organic groups other than aryl groups included in component (C-3) are as described for components (A) and (B) above.

The cyclic organopolysiloxane of component (C-3) can preferably be represented by average structural formula (V-3): (R¹²SiO)ₙ (in formula (V-3), R¹ are optionally halogen-substituted monovalent hydrocarbon groups, which may be the same or different, provided that at least two R¹ per molecule are alkenyl groups, and n is about 4 to 6).

In Formula (V-3) above, the optionally halogen-substituted monovalent hydrocarbon groups of R¹ can be the same as those in formula (I) above.

The content of the alkenyl groups in all of the silicon atom-bonded organic groups of the cyclic organopolysiloxane of component (C-3) can be designed as desired, but can usually be about 20 mol % or more, preferably about 30 mol % or more, and more preferably about 40 mol % or more, and can be about 80 mol % or less, preferably about 70 mol % or less, and more preferably about 60 mol % or less.

According to one embodiment of the present disclosure, the cyclic organopolysiloxane of component (C-3) is exemplified by having a low aryl group content. The aryl group content in component (C-3) (mol % of aryl groups in all silicon atom-bonded groups) can be, for example, about 10 mol % or less, preferably about 5 mol % or less, more preferably about 3 mol % or less, even more preferably about 1 mol % or less, and in particular about 0.5 mol % or less. In a preferred embodiment, component (C-3) contains no aryl groups.

When the curable silicone composition according to the present disclosure includes the (C-3) cyclic organopolysiloxane, the content of component (C-3) is not particularly limited, but can preferably be about 0.3% by mass or more, more preferably about 0.5% by mass or more, and even more preferably about 1% by mass or more, based on the total mass of the curable silicone composition of the present disclosure or the total mass of all organopolysiloxane components included in the composition. The content of component (C-3) can also be about 20% by mass or less, preferably about 15% by mass or less, and more preferably about 10% by mass or less, based on the total mass of the curable silicone composition or the total mass of all organopolysiloxane components included in the composition.

In one embodiment, the content of component (C-3) is from about 0.3 to about 20% by mass, preferably from about 0.5 to about 15% by mass, and even more preferably from about 1 to about 10% by mass, based on the total mass of the curable silicone composition of the present disclosure or the total mass of all organopolysiloxane components included in the composition.

In one embodiment, the total content of component (C) included in the curable silicone composition according to the present disclosure is about 3% by mass or more, preferably about 5% by mass or more, and even more preferably about 8% by mass or more, and can be about 50% by mass or less, preferably about 40% by mass or less, and more preferably about 35% by mass or less, based on the total mass of the curable silicone composition of the present disclosure or the total mass of all organopolysiloxane components included in the composition.

In one embodiment, the total content of component (C) included in the curable silicone composition according to the present disclosure is from about 3 to about 50% by mass, preferably from about 5 to about 40% by mass, and even more preferably from about 8 to about 35% by mass, based on the total mass of the curable silicone composition of the present disclosure or the total mass of all organopolysiloxane components included in the composition.

In a preferred embodiment, component (C) includes at least one type of component (C-1) in the interests of improving the permeability of the cured product.

When component (C) of the present disclosure includes component (C-1), the content of component (C-1) is about 20% by mass to about 48% by mass relative to the total content of component (A-1) and component (C-1). The content of component (C-1) is preferably about 25% by mass to about 48% by mass relative to the total content of component (A-1) and component (C-1).

In a preferred embodiment of the present disclosure, the total content of components (A-2) and (B-1) is about 20% by mass or more, and more preferably about 25% by mass or more, relative to the total mass of the curable silicone composition of the present disclosure or the total mass of all organopolysiloxane components included in the composition.

In a preferred embodiment of the present disclosure, the total content of component (C) is also about 10% by mass or more relative to the total content of components (A-2), (B-1), and (C) (specifically, C/(A-2+B-1+C)). In a preferred embodiment of the present disclosure, the total content of component (A-1) is also about 60% by mass or less relative to the total content of components (A-1), (A-2), and (B-1) (specifically, A-1/(A-1+A-2+B-1+C)). Such a composition of organopolysiloxane components will result in a cured product that has better crack resistance and high hardness.

### Other Organopolysiloxane Components

The curable silicone composition of the present disclosure may also include other organopolysiloxane components in addition to components (A) through (C) above. Examples of such other organopolysiloxanes include: component (A-3), which is an MQ resinous alkenyl group-containing organopolysiloxane that is a liquid at about 25° C., includes at least two alkenyl groups per molecule, and contains no aryl groups; and epoxy group-containing organopolysiloxanes serving as an (f) additive.

Component (a-3): MQ Resinous Organopolysiloxane that is a Liquid at about 25° C. And Includes at Least Two Alkenyl Groups Per Molecule

The curable silicone composition according to the present disclosure may also comprise, as component (A-3), an MQ resinous organopolysiloxane consisting of only M and Q units, that comprises at least two alkenyl groups per molecule and is a liquid at about 25° C. The curable silicone composition according to the present disclosure may comprise one type of component (A-3) MQ resinous organopolysiloxane, or may comprise two or more types of component (A-3) MQ resinous organopolysiloxanes. Component (A-3) is a liquid at about 25° C. and is therefore different from the MQ resinous alkenyl group-containing organopolysiloxane of component (A-2), which is a solid at about 25° C.

Examples of silicon atom-bonded organic groups included in component (A-3) include alkenyl groups and monovalent hydrocarbon groups other than alkenyl groups, which are described for component (A) above. The silicon atoms in component (A-3) may have a small quantity of hydroxyl groups or alkoxy groups such as methoxy or ethoxy groups, provided that the object of the present disclosure is not thereby compromised. Silicon atom-bonded organic groups in component (A-3) are preferably selected from among C1-6 alkyl groups, methyl in particular, and C2-12 alkenyl groups, vinyl in particular. In one embodiment, component (A-3) does not contain any epoxy group-containing organic groups as silicon atom-bonded organic groups.

Component (A-3) does not contain any aryl groups as silicon atom-bonded organic groups. Examples of such aryl groups are described for component (A) above.

In a preferred embodiment of the present disclosure, the MQ resinous organopolysiloxane of component (A-3) is preferably represented by the following average unit formula (VI).

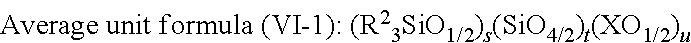

In the formula, R² indicates optionally halogen-substituted monovalent hydrocarbon groups other than aryl groups, which may be the same or different, provided that at least two R² per molecule are alkenyl groups, about 0<s<1, 0<t<1, 0≤u<0.4, and s+t=1). The symbol u represents the number of (XO) groups per silicon atom (ratio of the number of (XO) groups per silicon atom).

R² and X in Formula (VI-1) above can be the same as those in Formula (II-1) above.

In Formula (VI-1), s is preferably in the range of about 0.3≤s≤0.9, more preferably in the range of about 0.45s≤0.8, and even more preferably in the range of about 0.5≤s≤0.7. In Formula (VI-1) above, t is preferably in the range of about 0.1≤t≤0.6, more preferably in the range of about 0.2≤t≤0.5, and in particular in the range of about 0.25≤t≤0.4. In Formula (VI-1) above, u is preferably in the range of about 0≤u≤0.3, more preferably in the range of about 0≤u≤0.2, and in particular in the range of about 0≤u≤0.1.

The content of the alkenyl groups in all of the silicon atom-bonded organic groups of the MQ resinous alkenyl group-containing organopolysiloxane of component (A-3) is not particularly limited, but may be, for example, about 0.1 mol % or more, preferably about 0.3 mol % or more, and more preferably about 0.5 mol % or more of the total of the silicon atom-bonded organic groups, and can be about 20 mol % or less, preferably about 15 mol % or less, and more preferably about 10 mol % or less of the total of the silicon atom-bonded organic groups.

The weight-average molecular weight of the MQ resinous organopolysiloxane of component (A-3) includes, but is not particularly limited to, the range of from about 300 to less than about 2,000. In the present specification, the weight-average molecular weight can be determined by GPC. MQ resinous organopolysiloxanes having a weight average molecular weight of less than about 2,000 can usually be liquids at about 25° C. In a preferred embodiment, the weight-average molecular weight of the MQ resinous organopolysiloxane of component (A-3) is within the range of from about 500 to about 1,800.

The proportion of Q units relative to the total of M and Q units in the MQ resinous organopolysiloxane of component (A-3) is not particularly limited, but is preferably about 40% or less. Usually, the lower the proportion of Q units per molecule, the more likely it can be a liquid at about 25° C.

When the curable silicone composition of the present disclosure includes component (A-3), the content thereof is not particularly limited, but is usually about 1% by mass or more, preferably about 2% by mass or more, and more preferably about 3% by mass or more, based on the total mass of the hot-melt curable silicone composition of the present disclosure or the total mass of all organopolysiloxane components included in the composition. The content of component (A-3) is also preferably about 20% by mass or less, more preferably about 15% by mass or less, and even more preferably about 10% by mass or less, based on the total mass of the curable silicone composition.

In one embodiment, the content of component (A-3) is usually from about 1 to about 20% by mass, preferably from about 2 to about 15% by mass, and even more preferably from about 3 to about 10% by mass, based on the total mass of the curable silicone composition of the present disclosure or the total mass of all organopolysiloxane components included in the composition.

The (f) epoxy group-containing organopolysiloxane can preferably be a tackifier. Epoxy group-containing organopolysiloxanes also differ from components (A) through (C) in that epoxy group-containing organic groups are included in at least the silicon atom-bonded organic groups.

Examples of the molecular structure of epoxy group-containing organopolysiloxanes are linear, linear with some branching, branched, cyclic, resinous, and 3D network structures, where resinous epoxy-group containing organopolysiloxanes are preferred. The curable silicone composition according to the present disclosure may comprise one type of epoxy group-containing organopolysiloxane, or may comprise combinations of two or more types of epoxy group-containing organopolysiloxanes.

Epoxy group-containing organopolysiloxanes can preferably contain alkenyl groups, examples of which include C2-12 alkenyl groups such as vinyl, allyl, butenyl, pentenyl, hexenyl, heptenyl, octenyl, nonenyl, decenyl, undecenyl, and dodecenyl groups, preferably vinyl groups, and can also contain epoxy group-containing organic groups, examples of which include: glycidoxy alkyl groups such as 2-glycidoxyethyl, 3-glycidoxypropyl and 4-glycidoxybutyl groups; epoxycyclohexylalkyl groups such as 2-(3,4-epoxycyclohexyl)-ethyl and 3-(3,4-epoxycyclohexyl)-propyl groups; and epoxyalkyl groups such as 3,4-epoxybutyl and 7,8-epoxyoctyl groups; glycidoxyalkyl groups are preferred, particularly 3-glycidoxypropyl groups.

Examples of silicon atom-bonded groups other than alkenyl groups and epoxy group-containing organic groups in epoxy group-containing organopolysiloxanes include optionally halogen-substituted monovalent hydrocarbon groups other than alkenyl groups and epoxy group-containing organic groups, such as: C1-12 alkyl groups such as methyl, ethyl, propyl, isopropyl, butyl, isobutyl, tert-butyl, pentyl, neopentyl, hexyl, cyclohexyl, heptyl, octyl, nonyl, decyl, undecyl, and dodecyl groups; C6-20 aryl groups such as phenyl, tolyl, xylyl, and naphthyl groups; C7-20 aralkyl groups such as benzyl, phenethyl, and phenylpropyl groups; and any of these groups in which some or all of the hydrogen atoms are substituted with halogen atoms such as fluorine, chlorine, and bromine atoms; C1-12 alkyl groups are preferred, particularly methyl groups.

Resinous epoxy group-containing organopolysiloxanes can preferably be represented by the following average unit formula (VI-2):

Average unit formula (VI-2): (R⁵₃SiO_{1/2})_{f}(R⁵₂SiO_{2/2})_{g}(R⁵SiO_{3/2})ₕ(SiO_{4/2})ᵢ(XO_{1/2})ⱼ

In the formula (VI-2), R⁵ are each independently an optionally halogen-substituted monovalent hydrocarbon group, provided that at least two R⁵ are alkenyl groups and at least one R⁵ is an epoxy group-containing organic group, X is a hydrogen atom or alkyl group, about 0≤f<1, 0≤f<1, 0≤h<0.9, 0≤i<0.5, 0≤j<0.4, f+g+h+i+j=1.0, and h+i>0.

In Formula (VI-2) above, examples of optionally halogen-substituted monovalent hydrocarbon groups represented by R⁵ include the above-mentioned alkenyl groups, epoxy group-containing organic groups, and monovalent hydrocarbon groups other than these. In Formula (VI-2) above, X is a hydrogen atom or an alkyl group. Preferred examples of alkyl groups represented by X include C1-3 alkyl groups, specifically, methyl, ethyl, and propyl groups.

In Formula (VI-2) above, f is preferably in the range of about 0.05≤f≤0.5, more preferably in the range of about 0.05≤f≤0.4, and even more preferably in the range of about 0.1≤f≤0.3. In Formula (VI-2) above, g is preferably in the range of about 0.1≤g≤0.6, more preferably in the range of about 0.15≤g≤0.5, and in particular in the range of about 0.2≤g≤0.4. In Formula (VI-2) above, h is preferably in the range of about 0.2≤h≤0.8, more preferably in the range of about 0.3≤h≤0.7, and particularly in the range of about 0.4≤h≤0.6. In Formula (VI-2) above, i is preferably in the range of about 0≤i≤0.4, more preferably in the range of about 0≤i≤0.25, and particularly in the range of about 0≤i≤0.1. In Formula (VI-2) above, j is preferably in the range of about 0.05≤j≤0.5, more preferably in the range of about 0.1≤j≤0.4, and in particular in the range of about 0.15≤j≤0.3.

In a preferred embodiment of the present disclosure, resinous epoxy group-containing organopolysiloxanes are such that h in Formula (VI-2) above is greater than 0, specifically, include T units. The epoxy group-containing resinous organopolysiloxanes may or may not, but preferably do not, include Q units.

In a preferred embodiment of the present disclosure, epoxy group-containing organopolysiloxanes have epoxy group-containing organic groups in the form of molecular side-chain pendant groups. Epoxy group-containing organopolysiloxanes preferably have epoxy group-containing organic groups in D units.

The amount of epoxy group-containing organic groups in all silicon atom-bonded organic groups in the epoxy group-containing organopolysiloxane is not particularly limited, but is preferably about 5 mol % or more, more preferably about 10 mol % or more, and even more preferably about 15 mol % or more, and is also, for example, about 40 mol % or less, and preferably about 30 mol % or less. The amount of the epoxy group-containing organic groups can be determined by analysis such as Fourier transform infrared spectrophotometry (FT-IR) or nuclear magnetic resonance (NMR).

The number-average molecular weight of the epoxy group-containing organopolysiloxanes is not particularly limited, but can range from about 1,000 to about 10,000.

The content of epoxy group-containing organopolysiloxanes is not particularly limited but can be included in an amount of preferably about 0.01% by mass or more, more preferably about 0.1% by mass or more, and still more preferably about 0.5% by mass or more based on the total mass of the curable hot-melt silicone composition of the present disclosure, and can also be included in an amount of about 10% by mass or less, more preferably about 5% by mass or less, and even more preferably about 3% by mass or less based on the total mass of the curable hot-melt silicone composition of the present disclosure.

In the interests of component compatibility, the curable silicone composition according to the present disclosure is exemplified by having a low content of any resinous alkenyl group-containing organopolysiloxanes that have at least two alkenyl groups and at least one aryl group per molecule, and have an aryl group content of more than about 30% by mass. Specifically, the content of resinous alkenyl group-containing organopolysiloxanes that have at least two alkenyl groups and at least one aryl group per molecule, and have an aryl group content of more than about 30% by mass, is about 15% by mass or less, more preferably about 10% by mass or less, even more preferably about 5% by mass or less, preferentially about 3% by mass or less, and in particular preferably about 1% by mass or less, based on the total mass of the curable silicone composition or the total mass of all organopolysiloxane components in the composition. In a particularly preferred embodiment of the present disclosure, the curable silicone composition according to the present disclosure does not contain any resinous alkenyl group-containing organopolysiloxanes that have at least two alkenyl groups and at least one aryl group per molecule, and have an aryl group content of more than about 30% by mass.

In the interests of component compatibility, the curable silicone composition according to the present disclosure is exemplified by having a low content of a linear organopolysiloxane that contains more than about 35 siloxane units. Specifically, the content of a linear organopolysiloxane that contains more than about 35 siloxane units is about 15% by mass or less, more preferably about 10% by mass or less, even more preferably about 5% by mass or less, preferentially about 3% by mass or less, and in particular preferably about 1% by mass or less, based on the total mass of the curable silicone composition or the total mass of all organopolysiloxane components in the composition. In a particularly preferred embodiment of the present disclosure, the curable silicone composition according to the present disclosure does not contain any linear organopolysiloxane that contains more than about 35 siloxane units.

The curable silicone composition of the present disclosure can also contain alkenyl group-containing organopolysiloxanes having a linear, branched, resinous, and/or three-dimensional network structure, provided that the effects of the present disclosure are not thereby compromised.

In a preferred embodiment of the present disclosure, the ratio between silicon atom-bonded alkenyl groups and silicon atom-bonded hydrogen atoms (H/Ak) included in all organopolysiloxane components of the curable silicone composition is such that the silicon atom-bonded hydrogen atoms are less than about 1.2 mols, preferably less than 1.1 mols, and are usually about 0.50 mols or more, preferably about 0.60 mols or more, and more preferably about 0.70 mols or more, per mol silicon atom-bonded alkenyl groups.

### (D) Curing Catalyst

The curing catalyst of component (D) is a hydrosilylation reaction curing catalyst, which is a catalyst for promoting curing of the curable silicone composition of the present disclosure. Examples of component (D) include platinum-based catalysts such as chloroplatinic acid, alcohol solutions of chloroplatinic acid, platinum-olefin complexes, complexes of platinum and 1,3-divinyl-1,1,3,3-tetramethyldisiloxane, and platinum-supporting powders; palladium-based catalysts such as tetrakis(triphenylphosphine) palladium, and mixtures of triphenylphosphine and palladium black; and rhodium-based catalysts; but platinum-based catalysts are particularly preferred.

Component (D) is blended in a catalytic amount; more specifically, when a platinum-based catalyst is used as component (D), the amount of platinum atoms is preferably about 0.01 ppm or more, more preferably about 0.1 ppm or more, and even more preferably about 1 ppm or more relative to the total mass of the curable silicone composition of the present disclosure, and can also preferably be about 50 ppm or less, more preferably about 40 ppm or less, and even more preferably about 35 ppm or less relative to the total mass of the curable silicone composition of the present disclosure.

### (E) a Reaction Inhibitor

The reaction inhibitor of component (E) is a hydrosilylation reaction inhibitor that inhibits the hydrosilylation reaction of the organopolysiloxane components of the present disclosure. Examples of such curing reaction inhibitors include: alkyne alcohols such as 2-methyl-3-butyn-2-ol, 3,5-dimethyl-1-hexyn-3-ol, 2-phenyl-3-butyn-2-ol, 1-ethynyl-1-cyclohexanol, and 1-ethynyl-2-cyclohexanol; enyne compounds such as 3-methyl-3-penten-1-yne, 3,5-dimethyl-3-hexen-1-yne; alkenyl group-containing low-molecular weight siloxanes such as tetramethyltetravinylcyclotetrasiloxane and tetramethyltetrahexenylcyclotetrasiloxane; alkynyloxysilanes such as methyl-tris(1,1-dimethylpropynyloxy) silane, vinyl-tris(1,1-dimethylpropynyloxy) silane, and methyl-tris-(3-methyl-1-butyn-3-oxy) silane; maleate esters such as diallyl maleate and bis(2-ethylhexyl) maleate; and disulfide compounds having a disulfide structure, such as di-dodecyl disulfide, di-decyl disulfide, and di-octyl disulfide. The hydrosilylation reaction inhibitor is preferably selected from alkyne alcohols and maleate esters, and in particular preferably includes an alkyne alcohol and a maleate ester. The reaction inhibitor is usually added in an amount of from about 0.001 to about 5% by mass of the total composition.

### Other Components

Optional components may be blended in the curable silicone composition of the present disclosure, provided that the objectives of the present disclosure are not thereby compromised. Examples of optional components include acetylene compounds, organic phosphorus compounds, vinyl group-containing siloxane compounds; inorganic fillers such as crushed quartz, silica, magnesium carbonate, diatomaceous earth, and inorganic fillers obtained by subjecting the surface of such inorganic fillers to hydrophobic treatment with an organosilicon compound; surface treatment agents, tackifiers, agents that confer heat resistance, agents that confer cold resistance, agents that confer flame retardance, agents that confer thixotropic properties, and phosphors. Such optional components are usually added in an amount of from about 0.001 to about 20% by mass of the total composition.

The curable silicone composition according to the present disclosure can be cured to form a cured product having excellent transparency. Specifically, the cured product of the curable silicone composition of the present disclosure has a light transmittance of preferably about 80% or more at a wavelength of from about 400 nm to about 700 nm. The light transmittance of the cured product of the curable silicone composition can be determined, for example, by measuring the cured product having an optical path length of 1 mm using a spectrophotometer.

The curable silicone composition according to the present disclosure can be cured to form a cured product having high hardness. The cured product obtained by curing the curable silicone composition of the present disclosure preferably has a hardness greater than D30, as determined using a type D durometer at about 25° C. The hardness, as determined using a type D durometer hardness, can be determined by employing a type D durometer according to JIS K 6253-1997 “Hardness testing methods for rubber, vulcanized or thermoplastic.”

The curable silicone composition of the present disclosure can be prepared by mixing the various components. The method for mixing the components may be a conventionally known method but is not particularly limited; for example, the composition can be prepared using a mixing device. Examples of such mixing devices include, but are not particularly limited to, single- and twin-screw continuous mixers, double roller mixers, Ross mixers, Hobart mixers, dental mixers, planetary mixers, kneader mixers, and Henschel mixers.

### Encapsulating Material and Adhesive

The present disclosure also relates to an encapsulating material or adhesive for semiconductors utilizing the curable silicone composition of the present disclosure. The configuration of the encapsulating material or adhesive of the present disclosure is not particularly limited, but is preferably in the form of a film or sheet, and can be provided in the form of an encapsulant film or laminated film for encapsulating semiconductors. Examples of semiconductors that can be encapsulated with the encapsulating material of the present disclosure include, but are not particularly limited to, semiconductors made of SiC or GaN, for example, and particularly optical semiconductors such as power semiconductors or light emitting diodes.

### Optical Semiconductor Element

The present disclosure also relates to an optical semiconductor element comprising the encapsulating material of the present disclosure. Examples of optical semiconductor elements include light-emitting diodes (LEDs), semiconductor lasers, photodiodes, phototransistors, and light emitters and light receivers for solid-state imaging and photocouplers, where light-emitting diodes (LEDs) are particularly preferred.

Light-emitting diodes (LEDs) produce emitted light from the upper, lower, left and right sides of the optical semiconductor element, so it is undesirable for components of the light-emitting diode (LED) to absorb light, and materials having high light transmittance or high reflectance are preferred for such components. Consequently, a substrate on which the optical semiconductor element is mounted also preferably comprises a material having high light transmittance or high reflectance. Examples of the substrate on which the optical semiconductor element is mounted include: conductive metals such as silver, gold and copper; non-conductive metals such as aluminum and nickel; thermoplastic resins mixed with white pigments, such as PPA and LCP; thermosetting resins containing white pigments, such as epoxy resins, BT resins, polyimide resins and silicone resins; and ceramics such as alumina and alumina nitride.

Specific embodiments of the present disclosure are presented below.

Embodiment 1: a curable silicone composition, comprising:
(A) a resinous alkenyl group-containing organopolysiloxane comprising (A-1) and (A-2) below;
   (A-1) resinous alkenyl group-containing organopolysiloxanes that include at least two alkenyl groups and at least one aryl group per molecule; and
   (A-2) MQ resinous alkenyl group-containing organopolysiloxanes that are solids at about 25° C., that include at least two alkenyl groups per molecule, and that contain no aryl groups;
(B) at least one organopolysiloxane selected from (B-1) and (B-2) below:
   (B-1) linear organopolysiloxanes including from about 7 to about 35 siloxane units, that include at least two silicon atom-bonded hydrogen atoms per molecule or at least two alkenyl groups per molecule in a terminal of the molecular chain;
   (B-2) resinous organohydrogenpolysiloxanes including at least two silicon atom-bonded hydrogen atoms per molecule;
(C) a silicone reactive compatibilizer, which is an organopolysiloxane having no more than about 6 siloxane units, selected from (C-1) linear organohydrogenpolysiloxanes including at least two silicon atom-bonded hydrogen atoms and at least one aryl group per molecule, (C-2) MQ resinous organopolysiloxanes including at least two alkenyl groups per molecule, and (C-3) cyclic organopolysiloxanes including at least two alkenyl groups per molecule;
(D) a curing catalyst; and
(E) a reaction inhibitor,
   wherein
the content of aryl groups included in component (A-1) is more than about 0% by mass and not more than about 30% by mass relative to the total mass of component (A-1);
the organopolysiloxanes of (B) comprise at least one organohydrogenpolysiloxane;
when component (C) includes component (C-1), the content of component (C-1) is about 20% by mass to about 48% by mass relative to the total content of component (A-1) and component (C-1);
the content of resinous alkenyl group-containing organopolysiloxanes that have at least two alkenyl groups and at least one aryl group per molecule, and have an aryl group content of more than about 30% by mass, is about 15% by mass or less based on the total mass of the curable silicone composition; and
the content of linear organopolysiloxanes including more than about 35 siloxane units is about 15% by mass or less based on the total mass of the curable silicone composition.

Embodiment 2: the curable silicone composition according to Embodiment 1, wherein the content of component (A-1) is from about 5 to about 50% by mass based on the total mass of the curable silicone composition of the present disclosure.

Embodiment 3: the curable silicone composition according to Embodiment 1 or 2, further comprising component (C-1).

Embodiment 4: the curable silicone composition according to any of Embodiments 1 through 3, wherein the total content of component (C) is 3 to about 50% by mass based on the total mass of the curable silicone composition.

Embodiment 5: the curable silicone composition according to any of Embodiments 1 through 4, wherein the total content of component (A-2) and component (B-1) is about 20% by mass or more based on the total mass of the curable silicone composition of the present disclosure.

Embodiment 6: the curable silicone composition according to any of Embodiments 1 through 5, wherein the total content of component (C) is about 10% by mass or more relative to the total content of component (A-2), component (B-1), and component (C).

Embodiment 7: the curable silicone composition according to any of Embodiments 1 through 6, wherein the content of component (A-1) is about 60% by mass or less relative to the total content of component (A-1), component (A-2), and component (B-1).

Embodiment 8: an encapsulating material or adhesive, comprising the curable silicone composition according to any of Embodiments 1 through 7.

Embodiment 9: An optical semiconductor device that has been sealed with the encapsulating material described in Embodiment 8.

### EXAMPLES

The curable silicone composition of the present disclosure is described in greater detail by employing the following examples and comparative examples.

Curable silicone compositions were prepared by mixing the components in the formulations (parts by mass) shown in the tables. Below, Me represents a methyl group, Vi represents a vinyl group, and Ph represents a phenyl group. The structures of the organopolysiloxane components are also shown in a simplified manner in the table, and the organic groups other than Me in the M, D, T, or Q units are shown in parentheses. The H/Vi ratio indicates the molar ratio between the silicon atom-bonded hydrogen atoms (H) and the vinyl groups (Vi) in the organopolysiloxane components. The “total aryl group content” indicates the amount of aryl groups (mol %) in all silicon atom-bonded organic groups in all organopolysiloxane components.

Component a-1: resinous alkenyl group-containing organopolysiloxane represented by average unit formula (Me₃SiO_{1/2})₁₄(Me₂ ViSiO_{1/2})₁₁(MeSiO_{3/2})₅₃(PhSiO_{3/2})₂₂ (aryl group content: about 20% by mass; weight-average molecular weight: about 6000)

Component a′-1-1: resinous alkenyl group-containing organopolysiloxane represented by (Me₃SiO_{1/2})₅(Me₂ViSiO_{1/2})₁₇(MeSiO_{3/2})₃₉(PhSiO_{3/2})₃₉ (aryl group content: about 31% by mass; weight-average molecular weight: about 2500)

Component a-′1-2: resinous alkenyl group-containing organopolysiloxane represented by (Me₃₂ViSiO_{1/2})₁₅(Me₂SiO_{2/2})₃₅(PhSiO_{3/2})₅₀ (aryl group content: about 37% by mass; weight-average molecular weight: about 2000)

Component a-2-1: alkenyl group-containing MQ resin that is a solid at about 25° C., represented by average unit formula (Me₃SiO_{1/2})₄₆(Me₂ ViSiO_{1/2})₅(SiO_{4/2})₄₉(OH)₆ (molecular weight: about 2800)

Component a-2-2: alkenyl group-containing MQ resin that is a solid at about 25° C., represented by average unit formula (Me₃SiO_{1/2})₄₁(Mez ViSiO_{1/2})₇(SiO_{4/2})₅₂(OH)₅ (molecular weight: about 2800)

Component a-2-3: alkenyl group-containing MQ resin that is a solid at about 25° C., represented by average unit formula (Me₃SiO_{1/2})_{45.6}(Me₂ ViSiO_{1/2})_{2.9}(SiO_{4/2})_{51.5}(OH)_{3.5}(molecular weight: about 3300)

Component a-2-4: alkenyl group-containing MQ resin that is a solid at about 25° C., represented by average unit formula (Me₃SiO_{1/2})_{47.9}(Me₂ViSiO_{1/2})_{0.9}(SiO_{4/2})_{51.2}(OH)_{4.3} (molecular weight: about 3300)

Component a-3-1: alkenyl group-containing MQ resin that is a solid at about 25° C., represented by average unit formula (Me₃SiO_{1/2})₄₅(Me₃ViSiO_{1/2})₁₅(SiO_{4/2})₄₀ (molecular weight: about 1000)

Component a-3-2: alkenyl group-containing MQ resin that is a solid at about 25° C., represented by average unit formula (Me₃SiO_{1/2})₂₅(Me₂ViSiO_{1/2})₃₇(SiO_{4/2})₃₈(OH)₄ (molecular weight: about 1500)

Component b-1-1: linear organohydrogenpolysiloxane represented by average structural formula HMe₂SiO(Me₂SiO)₂₀SiHMe₂

Component b-1-2: linear alkenyl group-containing organopolysiloxane represented by average structural formula ViMe₂SiO(Me₂SiO)_{10.3}SiViMe₂

Component b′-1-1: linear organohydrogenpolysiloxane represented by average structural formula HMe₂SiO(Me₂SiO)₅₀SiHMe₂

Component b′-1-2: linear alkenyl group-containing organopolysiloxane represented by average structural formula ViMe₂SiO(Me₂SiO)₄₀SiViMe₂

Component b-2-1: MT resinous organohydrogenpolysiloxane represented by (HMe₂SiO_{1/2})₆₀(PhSiO_{3/2})₄₀ (molecular weight: about 750)

Component b-2-2: MQ resinous organohydrogenpolysiloxane represented by (HMe₂SiO_{1/2})₆₂(SiO_{4/2})₃₈ (molecular weight: about 1600)

Component c-1: linear organohydrogenpolysiloxane reactive compatibilizer represented by average structural formula HMe₂SiO(Ph₂SiO)SiHMe₂

Component c-2: MQ resinous organopolysiloxane reactive compatibilizer represented by average structural formula (ViMe₂SiO_{1/2})₄(SiO_{4/2})

Component c-3: cyclic alkenyl group-containing organopolysiloxane reactive compatibilizer represented by average structural formula (ViMeSiO)₄

Component d: Complex of platinum and divinyltetramethyldisiloxane having a platinum concentration of about 3.0% by mass

Component e: 1-ethynyl-1-cyclohexanol

Component f: resinous epoxy group-containing organopolysiloxane (serving as additive) represented by average unit formula (ViMe₂SiO_{1/2})₁₃(EpMeSiO_{2/2})₂₄(PhSiO_{3/2})₄₆(OMe)₁₇

Component g: fumed silica (surface treated with hexamethyldisilazane and trimethylsilane)

### Assessment

The following parameters were assessed and tested. However, Comparative Examples 5 through 10, 13, 14, 16 through 18, and 20 were not assessed or tested because the components were not compatible with each other, preventing uniform curable silicone compositions from being obtained.

### Light Transmittance

The curable silicone compositions that had been obtained were placed between two transparent glass sheets and were cured by being heated to about 150° C. for about 1 hour to prepare test pieces having an optical path length of about 1 mm. The light transmittance of the test pieces was determined at about 25° C. using a self-recording spectrophotometer capable of measurement at any wavelength in the range of visible light (wavelengths of from about 400 nm to about 700 nm). A light transmittance greater than about 80% was rated OK, and a light transmittance of about ≤80% was rated NG.

### Hardness of Cured Product

The curable silicone compositions that had been obtained were cured for about 1 hour at about 150° C., about 10 mm thick test specimens were prepared, and the hardness at about 25° C. was determined using a Durometer D hardness tester. A hardness greater than D30 was rated OK, and a hardness of D30 or less was rated NG.

### Die Shear Strength

about 25 mm×about 75 mm aluminum boards were used as substrates, and five 5 mm×5 mm×1 mm aluminum chips were used as bonding chips. Curable silicone composition (about 0.0080 g±0.0005 g) for each chip was applied onto the boards, the chips were placed thereon, and the chips were then bonded to the boards via about 2 hours of curing at about 150° C. The die shear strength was determ about ined using a bond tester (model number: SS-30WD; test mode: PH50 push; speed: 0.120 mm/sec). A die shear strength greater than about 500 kPa was rated OK, and a die shear strength of about 500 kPa or lower was rated NG.

### Post-Heat Treatment Cracking

The curable silicone compositions that had been obtained were cured for about 1 hour at about 150° C., about 10 mm thick test specimens were prepared and were then subjected to about 1,000 cycles of about 40° C. to about 125° C., and the cured products were then visually inspected for cracks. In one cycle, the temperature was held at about 40° C. and about 125° C. for about 30 minutes each. Specimens with no observable cracks were rated OK, and specimens with cracks were rated NG.

The results are shown in the following tables.

TABLE 1

| | | Example | Example | Example | Example | Example | Example | Example |
|---|---|---|---|---|---|---|---|---|
| Component | | 1 | 2 | 3 | 4 | 5 | 6 | 7 |
| a-1 | M₁₄M(Vi)₁₁T₈₈T(Ph)₂₂ | 22.3 | 23.3 | 23.7 | 34.3 | 24.0 | 29.1 | 29.3 |
| a-2-2 | M₄₁M(Vi)₇Q₅₁(OH)₆ | 30 | 30 | 30 | 15 | 30 | 30 | 30 |
| a-3-1 | M₄₅M(Vi)₁₅Q₄₀ | — | — | — | 2.8 | — | — | — |
| a-3-2 | M₂₈M(Vi)₈₇Q₈₈(OH)₄ | — | — | — | 2.5 | — | — | — |
| b-1-1 | M(H)D₂₀M(H) | 20 | 20 | 20 | 10 | — | 5 | — |
| b-1-2 | M(Vi)D_{10.3}M(H) | — | — | — | — | 20 | 15 | — |
| b-2-1 | M(H)₆₀T(Ph)₄₀ | 5 | 5 | 2.5 | 2.3 | 5 | 5 | 2.5 |
| b-2-2 | M(H)₆₂Q₃₈ | — | — | — | 1.6 | — | — | — |
| c-1 | M(H)D(PH₂)M(H) | 10.1 | 9.1 | 11.7 | 15.7 | 14.2 | 10.1 | 23.7 |
| c-2 | M(Vi)₄Q | — | 6.7 | — | 5.8 | 1 | — | 8.7 |
| c-3 | D(Vi)₄ | 6.7 | — | 6.7 | 3.4 | — | — | — |
| e | ETCH | 0.3 | 0.3 | 0.3 | 0.3 | 0.3 | 0.3 | 0.3 |
| f | M(Vi)₁₃(D(Ep)₂₄T(PH)₄₆(OMe)₁₇ | 1 | 1 | 1 | 1.8 | 1 | 1 | 1 |
| g | Fumed silica | 4.5 | 4.5 | 4.0 | 4.8 | 4.5 | 1.5 | 4.5 |
| Total | | 100 | 100 | 100 | 100 | 100 | 100 | 100 |
| d | Pt catalyst (Pt content: ppm) | 5 | 5 | 5 | 5 | 5 | 5 | 5 |

| | | | | | | | |
|---|---|---|---|---|---|---|---|
| H/Vi | 0.88 | 0.93 | 0.82 | 0.81 | 1.04 | 1.00 | 1.06 |
| (C-1)/((A-1) + (C-1)) | 31.1 | 28.1 | 33.0 | 31.3 | 37.2 | 25.8 | 44.7 |
| Assessment | | | | | | | |
| Light Transmittance | OK | OK | OK | OK | OK | OK | OK |
| Hardness | OK | OK | OK | OK | OK | OK | OK |
| Die shear strength | OK | OK | OK | OK | OK | OK | OK |
| Crack resistance | OK | OK | OK | OK | OK | OK | OK |

TABLE 2

| | | Example | Example | Example | Example | Example | Example | Example |
|---|---|---|---|---|---|---|---|---|
| Component | | 8 | 9 | 10 | 11 | 12 | 13 | 14 |
| a-1 | M₁₄M(Vi)₁₁T₅₃T(Ph)₂₂ | 31 | 18.6 | 18.9 | 12.8 | 17 | 17 | 17 |
| a-2-1 | M₄₆M(Vi)₅Q₄₉(OH)₆ | 30 | 58 | 60 | — | — | — | — |
| a-2-3 | M₄₅M(Vi)₁₅Q₄₀ | — | — | — | 60 | 1 | 61 | — |
| a-2-4 | M₂₈M(Vi)₅₇Q₈₈(OH)₄ | — | — | — | — | 60 | — | 61 |
| b-1-1 | M(H)D₂₀M(H) | — | 10 | 5 | 10 | 10 | 10 | 10 |
| b-2-1 | M(H)D₆₀T(PH)₄₀ | 2.5 | — | — | — | — | — | — |
| c-1 | M(H)D(PH₂)M(H) | 22 | 10 | 13 | 11.1 | 8 | 7.8 | 8.5 |
| c-2 | M(Vi)₄Q | 8.7 | 6.3 | 1 | 5.9 | 4.8 | 2.1 | 1.3 |
| c-3 | D(Vi)₄ | — | — | 2 | — | — | 2 | 2 |
| e | ETCH | 0.3 | 0.1 | 0.2 | 0.2 | 0.2 | 0.2 | 0.2 |
| f | M(Vi)₁₃(D(Ep)₂₄T(PH)₄₆(OMe)₁₇ | 1 | — | — | — | — | — | — |
| g | Fumed silica | 4.5 | — | — | — | — | — | — |
| Total | | 100 | 100 | 100 | 100 | 100 | 100 | 100 |
| d | Pt catalyst (Pt content: ppm) | 5 | 2 | 4 | 4 | 4 | 4 | |

| | | | | | | | |
|---|---|---|---|---|---|---|---|
| H/Vi | 1.03 | 0.61 | 0.85 | 0.86 | 0.86 | 0.86 | 0.80 |
| (C-1)/((A-1) + (C-1)) | 41.5 | 34.8 | 40.8 | 46.5 | 32.1 | 31.3 | 33.3 |
| Assessment | | | | | | | |
| Light Transmittance | OK | OK | OK | OK | OK | OK | OK |
| Hardness | OK | OK | OK | OK | OK | OK | OK |
| Die shear strength | OK | OK | OK | OK | OK | OK | OK |
| Crack resistance | OK | OK | OK | OK | OK | OK | OK |

TABLE 3

| | | Com- | Com- | Com- | Com- | Com- | Com- | Com- |
|---|---|---|---|---|---|---|---|---|
| | | parative | parative | parative | parative | parative | parative | parative |
| Component | | Example 1 | Example 2 | Example 3 | Example 4 | Example 5 | Example 6 | Example 7 |
| a-1 | M₁₄M(Vi)₁₁T₅₃T(Ph)₂₂ | 44.8 | 44.8 | 38.7 | 27.8 | — | 4.3 | — |
| a′-1-2 | M(Vi)₁₅T₃₅T(Ph)₃₀ | — | — | — | 20 | 58.7 | 55.2 | 57.7 |
| a-2-1 | M₄₆M(Vi)₅Q₄₉(OH)₆ | — | — | — | — | — | 5 | 10 |
| a-3-1 | M₄₅M(Vi)₁₅Q₄₀ | — | 10 | 10 | — | — | — | — |
| a-3-2 | M₂₆M(Vi)₅₇Q₈₈(OH)₄ | 5 | — | — | 5 | — | — | — |
| b-1-1 | M(H)D₂₀M(H) | — | 10 | 10 | — | 28 | 19 | 14 |
| b-2-1 | M(H)₆₀T(PH)₄₀ | — | — | 13.3 | 4 | — | — | — |
| b-2-2 | M(H)₆₂Q₅₃ | 3 | 3.0 | 3 | 3 | 5 | 5 | 5 |
| c-1 | M(H)D(PH₂)M(H) | 27.2 | 17.2 | 6.8 | 20.2 | — | 3.3 | 5 |
| c-2 | M(Vi)₄Q | 11.7 | 8.7 | 9.7 | 11.7 | — | — | — |
| e | ETCH | 0.3 | 0.3 | 0.6 | 0.3 | 0.3 | 0.3 | 0.3 |
| f | M(Vi)₁₃(D(Ep)₂₄ | 2.5 | 2.5 | 2.5 | 2.5 | 2.5 | 2.5 | 2.5 |
| | T(PH)₄₆(OMe)₁₇ | | | | | | | |
| g | Fumed silica | 6.5 | 5.5 | 5.5 | 5.5 | 5.8 | 5.5 | 6.5 |
| Total | | 100 | 100 | 100 | 100 | 100 | 100 | 100 |
| d | Pt catalyst (Pt content: ppm) | 5 | 5 | 5 | 5 | 5 | 5 | 5 |

| | | | | | | | |
|---|---|---|---|---|---|---|---|
| H/Vi | 1.00 | 1.04 | 1.07 | 0.90 | 1.01 | 1.03 | 1.06 |
| (C-1)/((A-1) + (C-1)) | 37.7 | 27.7 | 15 | 42 | — | 43.3 | 100 |
| Assessment | | | | | | | |
| Light Transmittance | OK | OK | OK | OK | Not | Not | Not |
| Hardness | OK | NG | OK | NG | compatible | compatible | compatible |
| Die shear strength | OK | NG | OK | NG | | | |
| Crack resistance | NG | OK | NG | OK | | | |

TABLE 4

| | | Com- | Com- | Com- | Com- | Com- | Com- | Com- |
|---|---|---|---|---|---|---|---|---|
| | | parative | parative | parative | parative | parative | parative | parative |
| Component | | Example 8 | Example 9 | Example 10 | Example 11 | Example 12 | Example 13 | Example 14 |
| a-1 | M₁₄M(Vi)₁₁T₅₃T(Ph)₂₂ | — | 8.6 | 4.3 | — | — | 10.2 | 10.2 |
| a′-1-2 | M(Vi)₁₅T₃₅T(Ph)₃₀ | 56.2 | 57.2 | 58.2 | 72.2 | 66.2 | 16.7 | 16.7 |
| a-2-1 | M₄₆M(Vi)₅Q₄₉(OH)₆ | 10 | 10 | 10 | — | — | 20 | 20 |
| a-3-2 | M₂₆M(Vi)₅₇Q₈₈(OH)₄ | 5 | — | — | — | — | — | — |
| b-1-1 | M(H)D₂₀M(H) | 10 | 6 | 10 | 10 | 5 | 30 | 30 |
| b-2-1 | M(H)D₆₀T(PH)₄₀ | — | — | — | — | — | 10 | — |
| b-2-2 | M(H)₆₂Q₅₃ | 5 | 5 | 5 | 5 | 11 | — | — |
| c-1 | M(H)D(PH₂)M(H) | 8 | 7.5 | 6.8 | 7 | 7 | 1.8 | 11.8 |
| c-3 | D(Vi)₄ | — | — | — | — | 5.0 | 5.5 | 5.5 |
| e | ETCH | 0.3 | 0.3 | 0.3 | 0.3 | 0.3 | 0.3 | 0.3 |
| f | M(Vi)₁₃(D(Ep)₂₄T | 1 | 1 | 3 | 1 | 1 | 1 | 1 |
| | (PH)₄₆(OMe)₁₇ | | | | | | | |
| g | Fumed silica | 4.5 | 4.5 | 4.5 | 4.5 | 4.5 | 4.5 | 4.5 |
| Total | | 100 | 100 | 100 | 100 | 100 | 100 | 100 |
| d | Pt catalyst (Pt content: ppm) | 5 | 5 | 5 | 5 | 5 | 5 | 5 |

| | | | | | | | |
|---|---|---|---|---|---|---|---|
| H/Vi | 0.98 | 1.01 | 1.06 | 1.00 | 1.02 | 1.02 | 0.97 |
| (C-1)((A-1) + (C-1)) | 100 | 46.9 | 61.4 | 100 | 100 | 15 | 63.6 |
| Assessment | | | | | | | |
| Light Transmittance | Not | Not | Not | OK | OK | Not | Not |
| Hardness | compatible | compatible | compatible | NG | NG | compatible | compatible |
| Die shear strength | | | | NG | NG | | |
| Crack resistance | | | | OK | OK | | |

TABLE 5

| | | Comparative | Comparative | Comparative | Comparative | Comparative |
|---|---|---|---|---|---|---|
| | Component | Example 15 | Example 16 | Example 17 | Example 18 | Example 19 |
| a-1 | M₁₄M(Vi)₁₁T₅₃T(Ph)₂₂ | 19.1 | — | 23.7 | 22.9 | 19.1 |
| a′-1-1 | M₅M(Vi)₁₇T₃₉T(Ph)₃₉ | — | 18.8 | — | — | — |
| a-2-2 | M₄₁M(Vi)₇Q₄₇(OH)₅ | 30 | 30 | 30 | 30 | 30 |
| a-3-1 | M₄₅M(Vi)₁₅Q₄₀ | — | — | — | 11.7 | — |
| b-1.1 | M(H)D₂₀M(H) | 20.0 | | | 20.0 | — |
| b′-1-1 | M(H)D₅₀M(H) | — | | 20.0 | — | — |
| b-1-2 | M(Vi)D_{10.3}M(Vi) | — | 24.7 | — | — | — |
| b′-1-2 | M(Vi)D₄₀M(Vi) | — | — | — | — | 26.7 |
| b-2-1 | M(H)₆₀T(Ph)₄₀ | — | 5 | 2.5 | 5 | 5 |
| c-1 | M(H)D(Ph₂)M(H) | 18.4 | 15.6 | 11.7 | 5.0 | 13.4 |
| c-2 | M(Vi)₄Q | — | — | — | — | — |
| c-3 | D(Vi)₄ | 6.7 | — | 6.7 | — | — |
| e | ETCH | 0.3 | 0.3 | 0.3 | 0.3 | 0.3 |
| f | M(Vi)₁₃D(Ep)₂₄T(Ph)₄₆(OMe)₁₇ | 1 | 1 | 1 | 1 | 1 |
| g | Fumed silica | 4.5 | 4.5 | 4 | 4 | 4.5 |
| Total | | 100 | 100 | 100 | 99.95 | 99.95 |
| d | d Pt catalyst (Pt content: ppm) | 5 | 5 | 5 | 5 | 5 |

| | | | | | |
|---|---|---|---|---|---|
| H/Vi | 1.04 | 1.04 | 0.70 | 1.10 | 1.58 |
| (C-1)/((A-1) + (C-1)) | 49.1 | 45.3 | 33 | 18 | 41.2 |
| Assessment | | | | | |
| Light Transmittance | OK | Not | Not | Not | Not |
| Hardness | NG | compatible | compatible | compatible | compatible |
| Die shear strength | NG | | | | |
| Crack resistance | OK | | | | |

As shown by the above results, the curable silicone compositions in the examples of the present disclosure were capable of forming cured products that had better transparency as well as high hardness and strength, and that had better crack resistance during changes in temperature.

### INDUSTRIAL APPLICABILITY

The curable silicone composition of the present disclosure is useful as an encapsulant, coating agent, or adhesive agent for optical semiconductor elements such as photoemitters and photodetectors for photocouplers, solid-state imaging, phototransistors, photodiodes, semiconductor lasers, light-emitting diodes (LEDs), etc.

While at least one exemplary embodiment has been presented in the foregoing detailed description, it should be appreciated that a vast number of variations exist. It should also be appreciated that the exemplary embodiment or exemplary embodiments are only examples, and are not intended to limit the scope, applicability, or configuration of the various embodiments in any way. Rather, the foregoing detailed description will provide those skilled in the art with a convenient road map for implementing an exemplary embodiment as contemplated herein. It being understood that various changes may be made in the function and arrangement of elements described in an exemplary embodiment without departing from the scope of the various embodiments as set forth in the appended claims.

What is claimed is:

1. A curable silicone composition comprising:
(A) a resinous alkenyl group-containing organopolysiloxane comprising (A-1) and (A-2) wherein:
(A-1) is a resinous alkenyl group-containing organopolysiloxane that includes at least two alkenyl groups and at least one aryl group per molecule;
(A-2) is an MQ resinous alkenyl group-containing organopolysiloxane that is solid at 25° C., that includes at least two alkenyl groups per molecule, and that contains no aryl groups;
(B) at least one organopolysiloxane chosen from (B-1) and (B-2) wherein:
(B-1) is a linear organopolysiloxane including 7 to 35 siloxane units, that includes at least two silicon atom-bonded hydrogen atoms per molecule or at least two alkenyl groups per molecule in a terminal of the molecular chain;
(B-2) is a resinous organohydrogenpolysiloxane including at least two silicon atom-bonded hydrogen atoms per molecule;
(C) a silicone reactive compatibilizer which is an organopolysiloxane having no more than 6 siloxane units, chosen from:
(C-1) linear organohydrogenpolysiloxanes including at least two silicon atom-bonded hydrogen atoms and at least one aryl group per molecule,
(C-2) MQ resinous organopolysiloxanes including at least two alkenyl groups per molecule, and
(C-3) cyclic organopolysiloxanes including at least two alkenyl groups per molecule;
(D) a curing catalyst; and
(E) a reaction inhibitor,
wherein
the content of aryl groups included in component (A-1) is more than 0% by mass and not more than 30% by mass relative to the total mass of component (A-1);
the organopolysiloxane of (B) comprises at least one organohydrogenpolysiloxane;
when component (C) includes component (C-1), the content of component (C-1) is 20% by mass to 48% by mass relative to the total content of component (A-1) and component (C-1);
the content of resinous alkenyl group-containing organopolysiloxanes that have at least two alkenyl groups and at least one aryl group per molecule, and have an aryl group content of more than 30% by mass, is 15% by mass or less based on the total mass of the curable silicone composition; and
the content of linear organopolysiloxanes including more than 35 siloxane units is 15% by mass or less based on the total mass of the curable silicone composition.

2. The curable silicone composition according to claim 1, wherein the content of component (A-1) is 5 to 50% by mass based on the total mass of the curable silicone composition.

3. The curable silicone composition according to claim 1, comprising component (C-1).

4. The curable silicone composition according to claim 1, wherein the total content of component (C) is 3 to 50% by mass based on the total mass of the curable silicone composition.

5. The curable silicone composition according to claim 1, wherein the total content of component (A-2) and component (B-1) is 20% by mass or more based on the total mass of the curable silicone composition.

6. The curable silicone composition according to claim 1, wherein the total content of component (C) is 10% by mass or more relative to the total content of component (A-2), component (B-1), and component (C).

7. The curable silicone composition according to claim 1, wherein the content of component (A-1) is 60% by mass or less relative to the total content of component (A-1), component (A-2), and component (B-1).

8. An encapsulating material or adhesive comprising the curable silicone composition according to claim 1.

9. An optical semiconductor device encapsulated with the encapsulating material according to claim 8.

10. The curable silicone composition according to claim 1 comprising (B-1).

11. The curable silicone composition according to claim 1 comprising (B-2).

12. The curable silicone composition according to claim 1 comprising (C-2).

13. The curable silicone composition according to claim 1 comprising (C-3).

14. The curable silicone composition according to claim 1 wherein (A-1) is present and is M₁₄M(Vi)₁₁T₅₃T(Ph)₂₂.

15. The curable silicone composition according to claim 1 wherein:
(A-1) is present and is M₁₄M(Vi)₁₁T₅₃T(Ph)₂₂; and
(A-2) is present and is M₄₁M(Vi)₇Q₅₂(OH)₅.

16. The curable silicone composition according to claim 15 wherein (C-1) is present and is M(H)D(Ph₂)MH.

17. The curable silicone composition according to claim 1 wherein:
(A-1) is present and is M₁₄M(Vi)₁₁T₅₃T(Ph)₂₂; and
(A-2) is present and is M₄₅M(Vi)₅Q₄₉(OH)₆.

18. The curable silicone composition according to claim 17 wherein (C-1) is present and is M(H)D(Ph₂)MH.

19. The curable silicone composition according to claim 1 wherein:
(A-1) is present and is M₁₄M(Vi)₁₁T₅₃T(Ph)₂₂; and
(B-1) is present and is M(H)D₂₀M(H).

20. The curable silicone composition according to claim 1 wherein:
(A-1) is present and is M₁₄M(Vi)₁₁T₅₃T(Ph)₂₂; and
(C-1) is present and is M(H)D(Ph₂)MH.
